(19) United States
(12) Patent Application Publication
(10) Pub. No.: US 2025/0077584 A1
(43) Pub. Date: Mar. 6, 2025

(54) SHAPLEY VALUE COMPUTATION WITH ANALOG CAM

(71) Applicant: HEWLETT PACKARD ENTERPRISE DEVELOPMENT LP, Spring, TX (US)

(72) Inventors: JOHN MOON, Spring, TX (US); GIACOMO PEDRETTI, Cernusco sul Naviglio (MI) (IT); CATHERINE GRAVES, Milpitas, CA (US)

(21) Appl. No.: 18/460,425

(22) Filed: Sep. 1, 2023

(51) Int. Cl. G06F 16/903

(52) U.S. Cl. CPC G06F 16/90339

(57) ABSTRACT

Examples of the presently disclosed technology provide hardware accelerators (referred to herein as treeShap-aCAMs) that compute Shapley values with improved speed/efficiency leveraging the unique parallel search and analog capabilities of aCAMs. The parallel search capability of a treeShap-aCAM enables evaluation of all root-to-leaf paths of a decision tree (programmed into separate rows of the treeShap-aCAM) in a single clock cycle, greatly reducing time required to compute Shapley values. Relatedly, a treeShap-aCAM's ability to store/evaluate analog values (as opposed to merely binary values), can reduce footprint and hardware (e.g., reduce the number of CAM cells) required to perform Shapley value computations. Accordingly, treeShap-aCAMs can compute Shapley values more rapidly/efficiently than other types of hardware accelerators that e.g., implement algorithms that traverse root-to-leaf paths of decision trees node-to-node.

### BACKGROUND

Content addressable memory (“CAM”) is a type of computing memory in which stored data is searched by its content rather than its location. When a “word” is input to a CAM, the CAM searches for the word in its contents. If the CAM finds the word (i.e., “returns a match”), the CAM returns the address of the location where the found word resides. Individual cells of a CAM (i.e., CAM cells) can be arranged into rows and columns. CAM cells of a common row may be connected along a common match line. Words can be stored along the rows of the CAM, and each CAM cell of a given row can store an entry of a stored word. When the CAM receives an input word (e.g., a series of voltage signals each representing an entry of the input word, sometimes referred to herein as an input vector), the CAM can search for the input word, by entry, along the columns of the CAM (i.e., a first entry of the input word can be searched down a first column of the CAM, a second entry of the input word can be searched down a second column of the CAM, etc.). The CAM can “find” the input word in a given row if all the CAM cells of the given row return a match for their respective entries of the input word.

Analog CAMs (“aCAMs”) are special types of CAMs that can store and search for ranges of values (in contrast to traditional digital-based CAMs which can only store/search for zeros and ones) using the programmable conductance of memristors.

### BRIEF DESCRIPTION OF THE DRAWINGS

The present disclosure, in accordance with one or more various examples, is described in detail with reference to the following figures. The figures are provided for purposes of illustration only and merely depict examples.

FIG. 1 depicts an example aCAM cell, in accordance with examples of the presently disclosed technology.

FIG. 2 depicts an example voltage range diagram, in accordance with examples of the presently disclosed technology.

FIG. 3 depicts another example voltage range diagram, in accordance with examples of the presently disclosed technology.

FIG. 4 depicts an example decision tree, in accordance with examples of the presently disclosed technology.

FIG. 5 depicts example feature chains, in accordance with examples of the presently disclosed technology.

FIG. 6 depicts an example representation of a decision tree in an aCAM, in accordance with examples of the presently disclosed technology.

FIG. 7 depicts an example process for computing Shapley values using an aCAM, in accordance with examples of the presently disclosed technology.

FIGS. 8A-8G depict an example use case for utilizing the example process from FIG. 7 to compute a Shapley value, in accordance with examples of the presently disclosed technology.

FIG. 9 depicts a block diagram of an example computer system in which various of the examples described herein may be implemented.

The figures are not exhaustive and do not limit the present disclosure to the precise form disclosed.

### DETAILED DESCRIPTION

Tree-based models (e.g., random forests, gradient boosted trees, etc.—sometimes referred to herein generally as decision trees) are popular machine learning models as they are simple to train, perform well with small data sets (especially tabular data sets), and can provide human-interpretable explanations. Examples of human-interpretable explanations include Shapley values (e.g., multi-valued vectors) that can measure contributions that individual input features make to a tree-based model decision.

Traditionally, a Shapley value is a solution concept in cooperative game theory where a coalition of “players” cooperates and achieves an overall gain from the cooperation. In this context, a Shapley value (e.g., a multi-valued vector) measures the contribution that individual players in a coalition game make to the overall gain achieved through coalitional cooperation. In other words, the Shapley value assigns a unique distribution—among individual players in the coalition game—of a total surplus/gain generated by coalitional cooperation.

While Shapley values can provide useful/insightful human-interpretable explanations for machine-learning applications, a historical barrier to real-time (or close to real-time) machine-learning model interpretability has been the large complexity, long processing times, and large hardware overhead required to compute Shapley values by conventional methods. Real-time (or close to real-time) human-interpretability can be extremely advantageous in time-sensitive applications (e.g., guided surgical interventions) where a human needs to make a quick decision based on a machine-learning model output. Accordingly, there is a serious opportunity for a hardware accelerator that can compute Shapley values with improved speed/efficiency.

Against this backdrop, examples of the presently disclosed technology provide hardware accelerators (referred to herein as treeSHAP-aCAMs) that compute Shapley values with improved speed/efficiency leveraging the unique parallel search and analog capabilities of aCAMs. For example, the parallel search capability of a treeSHAP-aCAM enables evaluation of all root-to-leaf paths of a decision tree (programmed into separate rows of the treeSHAP-aCAM) in a single clock cycle, greatly reducing time required to compute Shapley values. Relatedly, a treeSHAP-aCAM's ability to store/evaluate analog values (as opposed to merely binary values), can reduce footprint and hardware (e.g., reduce the number of CAM cells) required to perform Shapley value computations. Accordingly, treeSHAP-aCAMs can compute Shapley values more rapidly/efficiently than other types of hardware accelerators that e.g., implement algorithms that traverse root-to-leaf paths of decision trees node-to-node.

Before describing treeSHAP-aCAMs of the presently disclosed technology in more detail, it should be understood that implementing (i.e., programming and evaluating) a Shapley problem using an aCAM presents a technological/computational challenge because Shapley problems are traditionally formulated using binary values/expressions. By contrast, aCAMs are traditionally used to implement problems involving analog values/expressions. As alluded to above, this analog capability of aCAMs allows them to implement problems more efficiently (e.g., with less hardware) than binary/digital alternatives.

To address the technological/computational challenge described above, examples of the presently disclosed technology provide a new methodology which enables Shapley value computation using analog values/expressions that are compatible with, and leverage, the unique analog and parallel search capabilities of aCAMs. Thus, leveraging this new analog value/expression-oriented Shapley value computation methodology, treeSHAP-aCAMs of the presently disclosed technology can utilize aCAMs to compute Shapley values more rapidly/efficiently than other types of hardware accelerators.

For example, a treeShap-aCAM of the present technology may comprise: (1) an analog content addressable memory (aCAM), wherein each row of the aCAM is programmed to represent a separate root-to-leaf path of a decision tree comprising evaluable conditions involving (M) features; and (2) one or more processing resources (e.g., a combination of logic circuits and one or more processors) operative to: (a) apply a first foreground input vector to the aCAM, wherein: (i) a first value of (M) total values of the first foreground input vector represents a first feature of (M) features from a foreground sample, and (ii) remaining (M−1) values of the (M) total values of the first foreground input vector represent wildcard values (sometimes referred to as “don't care” or “always match” values); (b) apply a first background input vector to the aCAM, wherein: (i) a first value of (M) total values of the first background input vector represents a first feature of (M) features from a background sample, (ii) remaining (M−1) values of the (M) total values of the first background input vector represent wildcard values; (c) based on match line outputs from the aCAM responsive to application of the first foreground and background input vectors, compute a first iteration of Shapley value computation parameters; (d) iterate steps (a)-(c) for each of the (M) features of the foreground and background samples to generate subsequent iterations of the Shapley value computation parameters; and (e) based on final iterations of the Shapley value computation parameters, compute a Shapley value for the foreground sample. As alluded to above, the Shapley value may comprise a multi-valued vector that measures contributions from the individual features of the foreground sample to a decision tree-based model decision.

In various implementations, iterating the steps (a)-(c) for a second feature of the (M) features of the foreground and background samples may comprise: (a) applying a second foreground input vector to the aCAM, wherein: (i) a second value of (M) total values of the second foreground input vector represents a second feature of the (M) features from the foreground sample, and (ii) remaining (M−1) values of the (M) total values of the second foreground input vector represent wildcard values; (b) applying a second background input vector to the aCAM, wherein: (i) a second value of (M) total values of the second background input vector represents a second feature of the (M) features from the background sample, and (ii) remaining (M−1) values of the (M) total values of the second background input vector represent wildcard values; and (c) based on match line outputs from the aCAM responsive to application of the second foreground and background input vectors, computing a second iteration of the Shapley value computation parameters.

In certain implementations, the Shapley value computation parameters may comprise: (1) a vector N representing, for each root-to-leaf path of the decision tree, a total number of unique features in the root-to-leaf path (here, dimension of the vector N may correspond with the number of root-to-leaf paths of the decision tree); (2) a vector S representing, for each root-to-leaf path of the decision tree, a total number of features of the root-to-leaf path that match the foreground sample (here again, dimension of the vector S may correspond with the number of root-to-leaf paths of the decision tree); (3) a matrix U representing, for each root-to-leaf path of the decision tree, offsets to the vector S applied when computing the Shapley value for the foreground sample (here, the number of rows of the matrix U may correspond with the number of root-to-leaf paths of the decision tree and the number of columns of the matrix U may correspond with the number of features of the foreground/background samples); (4) a matrix V representing, for each root-to-leaf path of the decision tree, contribution types for the root-to-leaf path (here again, the number of rows of the matrix V may correspond with the number of root-to-leaf paths of the decision tree and the number of columns of the matrix V may correspond with the number of features of the foreground/background samples); and (5) a vector P representing, for each root-to-leaf path of the decision tree, path validity of the root-to-leaf path (here again, dimension of the vector P may correspond with the number of root-to-leaf paths of the decision tree).

In some implementations, computing the first iteration of the vector N may comprise adding, to an all-zero vector, an exclusive OR (XOR) between a first foreground match line output vector y_{f1} representing match line outputs responsive to application of the first foreground input vector to the aCAM and a first background match line output vector y_{b1} representing match line outputs responsive to application of the first background input vector to the aCAM. Here, the all-zero vector, the first foreground match line output vector y_{f1}, and the first background match line output vector y_{b1} may all have a dimension corresponding with the number of root-to-leaf paths of the decision tree (which again, also corresponds with the number of programmed rows of the aCAM). Similarly, computing the first iteration of the vector S may comprise adding, to an all-zero vector, a conjunction (i.e., a logical AND operation) between the first foreground match line output vector y_{f1} and a negation (i.e., a logical NOT operation) of the first background match line output vector y_{b1}. Computing the first iteration of the matrix U may comprise populating a first column of the matrix U with the conjunction between the first foreground match line output vector y_{f1} and the negation of the first background match line output vector y_{b1}. Computing the first iteration of the matrix V may comprise populating a first column of the matrix V with a subtraction, from the conjunction between the first foreground match line output vector y_{f1} and the negation of the first background match line output vector y_{b1}, of a conjunction between a negation of the first match line output vector y_{f1} and the first background match line output vector y_{b1}. Finally, computing the first iteration of the vector P may comprise performing a conjunction between an all-one vector (also having a dimension corresponding with the number of root-to-leaf paths of the decision tree/the number of programmed rows of the aCAM) and a disjunction (i.e., a logical OR operation) between the first foreground match line output vector y_{f1} and the first background match line output vector y_{b1}.

In various implementations, computing the second iteration of the vector N may comprise adding, to the first iteration of the vector N, an XOR between a second foreground match line output vector y_{f2} representing match line outputs responsive to application of the second foreground input vector to the aCAM and a second background match line output vector y_{b2} representing match line outputs responsive to application of the second background input vector to the aCAM. Similarly, computing the second iteration of the vector S may comprise adding, to the first iteration of the vector S, a conjunction between the second foreground match line output vector y_{f2} and a negation of the second background match line output vector y_{b2}. Computing the second iteration of the matrix U may comprise populating a second column of the matrix U with the conjunction between the second foreground match line output vector y_{f2} and the negation of the second background match line output vector y_{b2}. Computing the second iteration of the matrix V may comprise populating a second column of the matrix V with a subtraction, from the conjunction between the second foreground match line output vector y_{f2} and the negation of the second background match line output vector y_{b2}, of a conjunction between a negation of the second foreground match line output vector y_{f2} and the second background match line output vector y_{b2}. Finally, computing the second iteration of the vector P may comprise performing a conjunction between the first iteration of the vector P and a disjunction between the second foreground match line output vector y_{f2} and the second background match line output vector y_{b2}.

Eqs. 1 below illustrate generalized expressions that treeSHAP-aCAMs of the presently disclosed technology can use to compute Shapley value computation parameters. Here, x_{f} represents a foreground sample comprising a total of (M) features, x_{b} represents a background sample also comprising a total of (M) features, TI represents lower boundary thresholds programmed into the aCAM, Th represents upper boundary thresholds programmed into the aCAM, and the other variables/symbols represent the vectors/matrices described above.

$$for i ← 1 to M do \qquad Eqs . 1$$

$${y}_{f} = aCAM ( {x}_{f} , i , Tl , Th )$$

$${y}_{b} = aCAM ( {x}_{b} , i , Tl , Th )$$

$$N = N + XOR ( {y}_{f} , {y}_{b} )$$

$$S = S + ( {y}_{f} ⋀ - {y}_{b} )$$

$$U \text{?} = {y}_{f} ⋀ - {y}_{b}$$

$$V \text{?} = ( {y}_{f} ⋀ - {y}_{b} ) - ( - {y}_{f} ⋀ {y}_{b} )$$

$$P = P ⋀ ( {y}_{f} ⋁ {y}_{b} )$$

$$\text{?} \text{indicates text missing or illegible when filed}$$

In some implementations, the one or more processing resources may be further operative to, responsive to final iteration of steps (a)-(c), update the final iteration of the matrix V by performing a conjunction between the final iteration of the matrix V and the final iteration of the vector P. This operation may be performed to ensure that only valid root-to-leaf paths of the decision tree contribute to a computed Shapley value. Thus, computing the Shapley value for the foreground sample based on the final iterations of the Shapley value computation parameters may comprise computing the Shapley value for the foreground sample based on the final iteration of the vector N, the final iteration of the vector S, the final iteration of the matrix U, the updated final iteration of the matrix V, and a vector v (also having a dimension corresponding to the number of root-to-leaf paths of the decision tree) representing leaf values of the decision tree.

In some implementations, the treeShap-aCAM may further comprise a resistive random-access memory (ReRAM) that stores leaf values of the decision tree. In these examples: (1) a first row of the aCAM may be programmed to store a first root-to-leaf path of the decision tree; (2) a first row of the ReRAM may be programmed to store a leaf of the first root-to-leaf path; and (3) the first row of the ReRAM may be electrically connected to a match line of the first row of the aCAM. Similarly: (1) a second row of the aCAM may be programmed to store a second root-to-leaf path of the decision tree; (2) a second row of the ReRAM may be programmed to store a leaf of the second root-to-leaf path; and (3) the second row of the ReRAM may be electrically connected to a match line of the second row of the aCAM.

In some of the implementations described above, a first column of the aCAM can store evaluable conditions of the decision tree corresponding with the first features of the foreground and background samples. Relatedly, a second column of the aCAM can store evaluable conditions of the decision tree corresponding with the second features of the foreground and background samples. In these examples, the first value of the (M) total values of the first foreground input vector (representing the first feature of the foreground sample) can be applied to the first column of the aCAM. Relatedly, the first value of the (M) total values of the first background input vector (representing the first feature of the background sample) can be applied to the first column of the aCAM. In these examples, the second value of the (M) total values of the second foreground input vector (representing the second feature of the foreground sample) can be applied to the second column of the aCAM. Relatedly, the second value of the (M) total values of the second background input vector (representing the second feature of the background sample) can be applied to the second column of the aCAM. Here, an aCAM cell belonging to the first row and the first column of the aCAM may be programmed to store one or more evaluable conditions of the first root-to-leaf path corresponding with the first features of the foreground and background samples. As described in greater detail below, the aCAM cell may comprise two memristors. Accordingly, programming the aCAM cell to store the one or more evaluable conditions of the first root-to-leaf path corresponding with the first features of the foreground and background samples may comprise programming conductances of the two memristors. As alluded to above, programming the conductances of the two memristors may cause the aCAM cell to store a lower boundary threshold voltage and an upper boundary threshold voltage representing the one or more evaluable conditions of the first root-to-leaf path corresponding with the first features of the foreground and background samples.

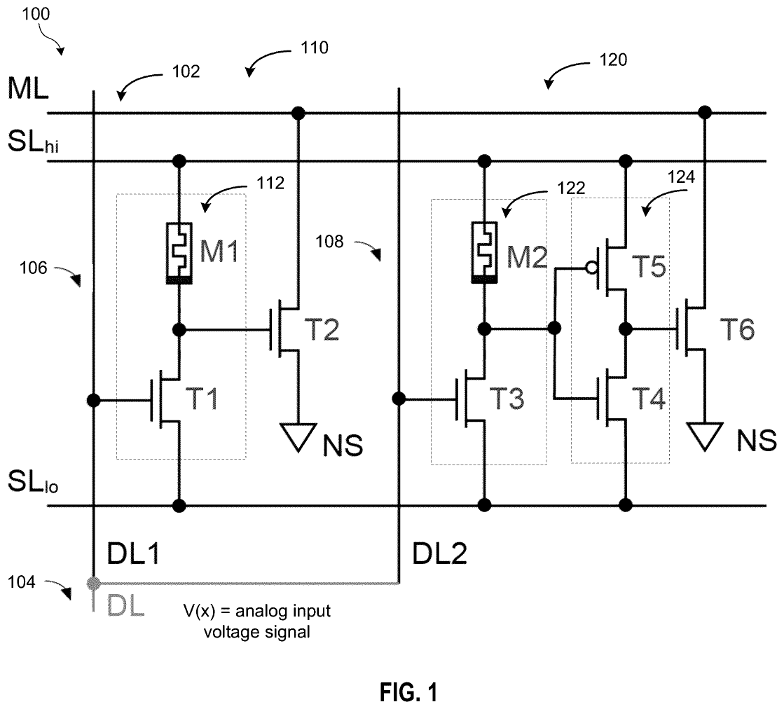

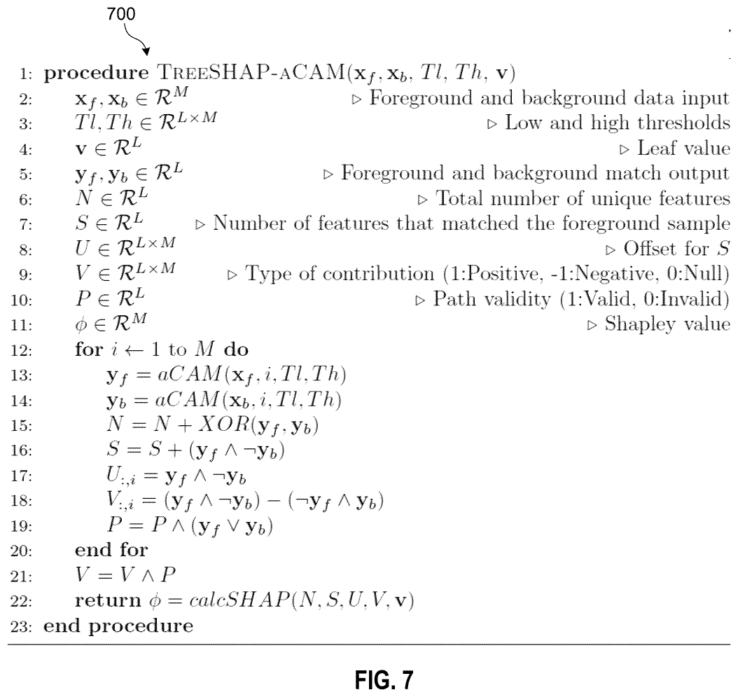

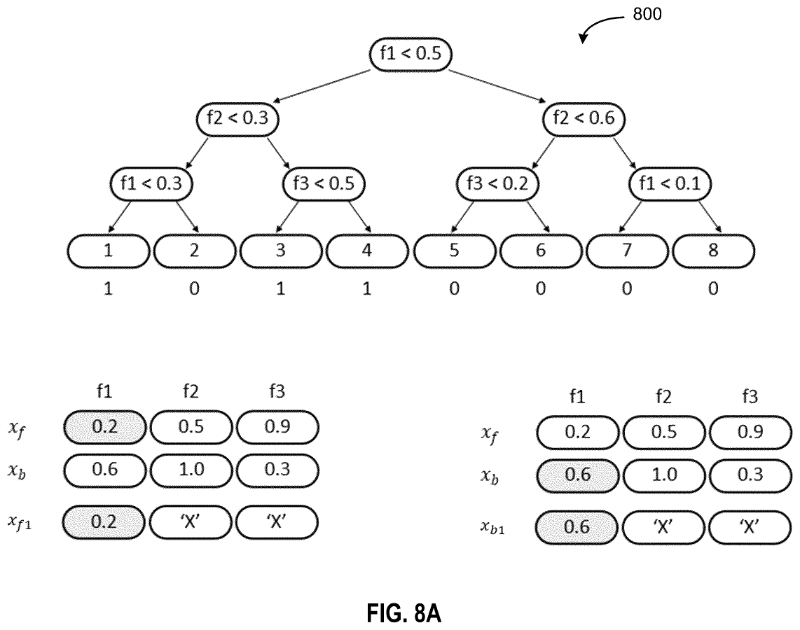

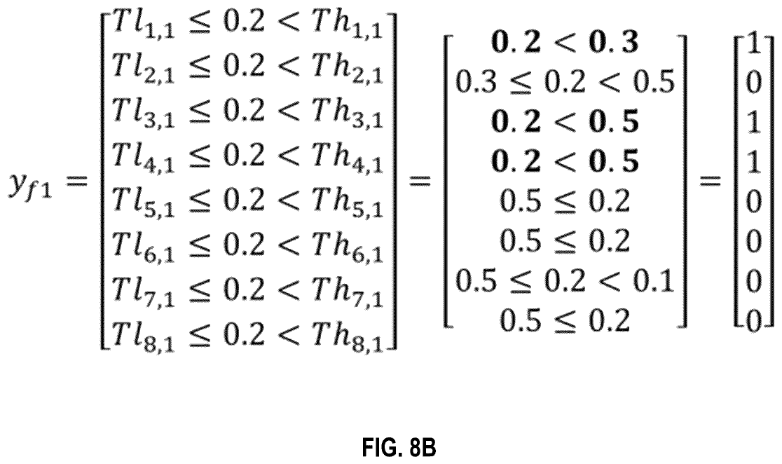

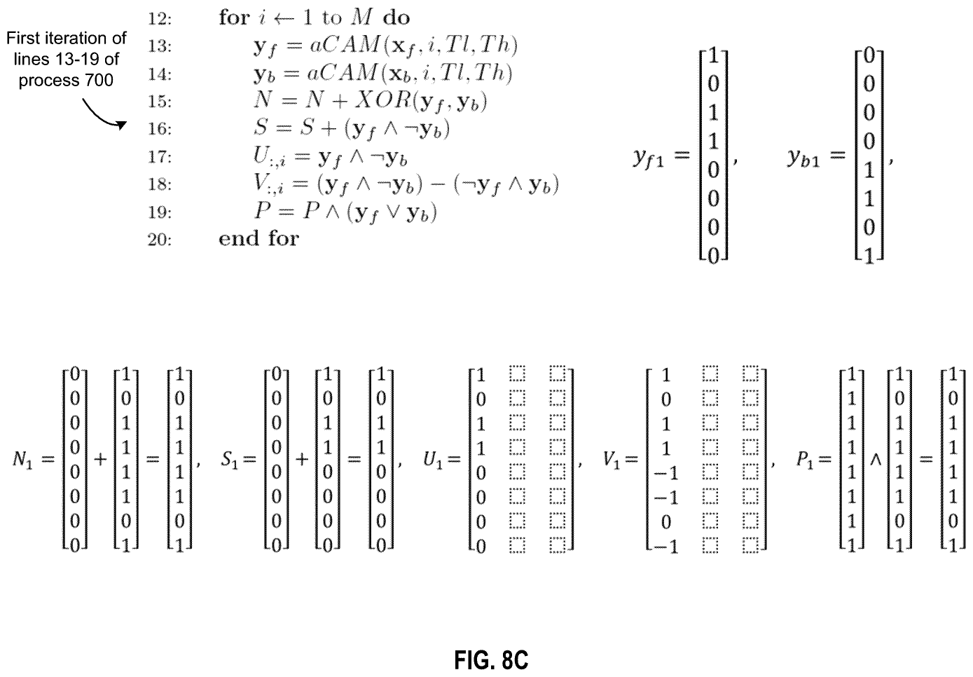

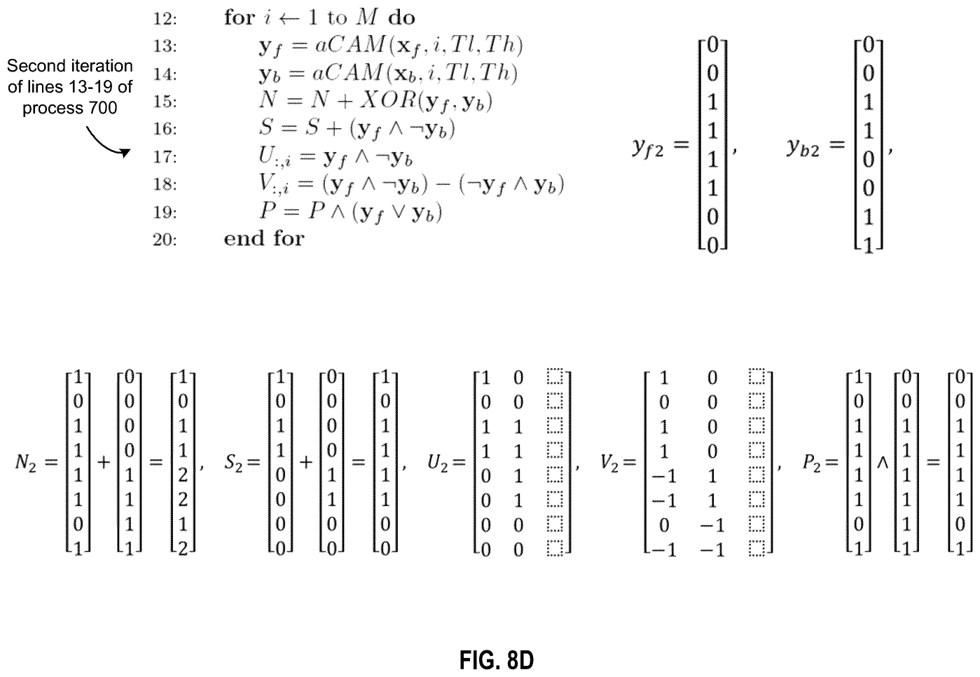

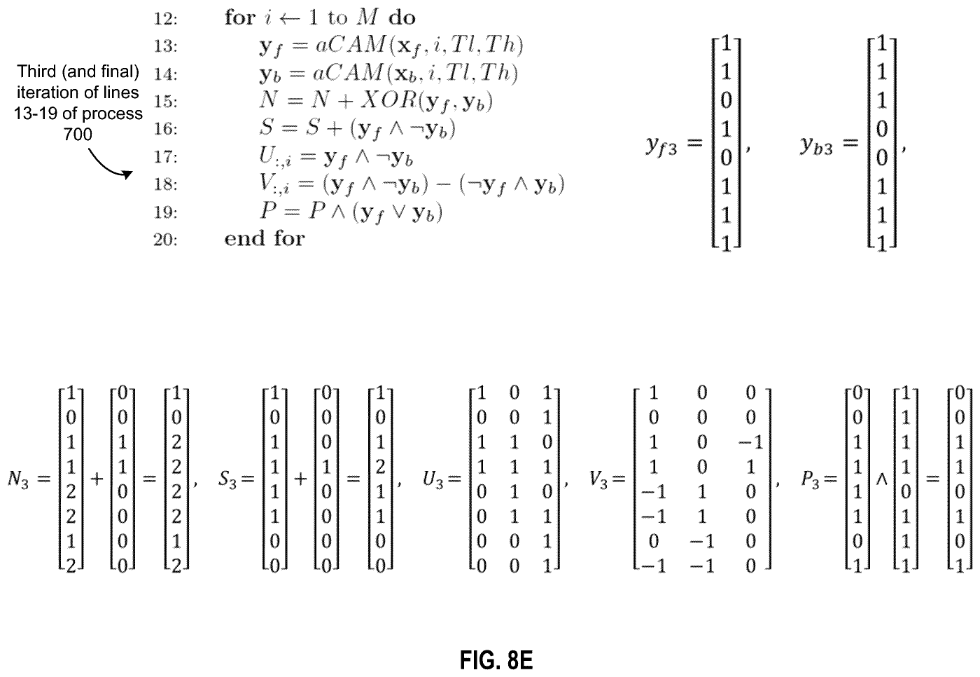

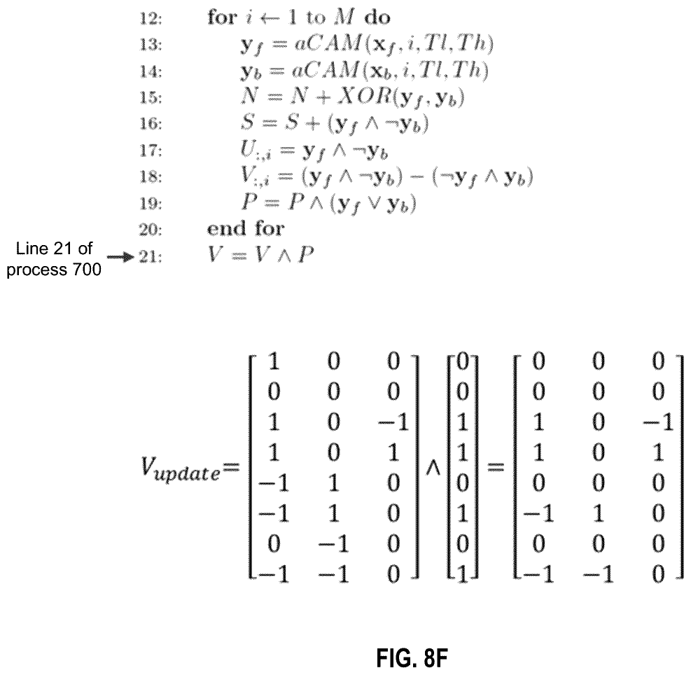

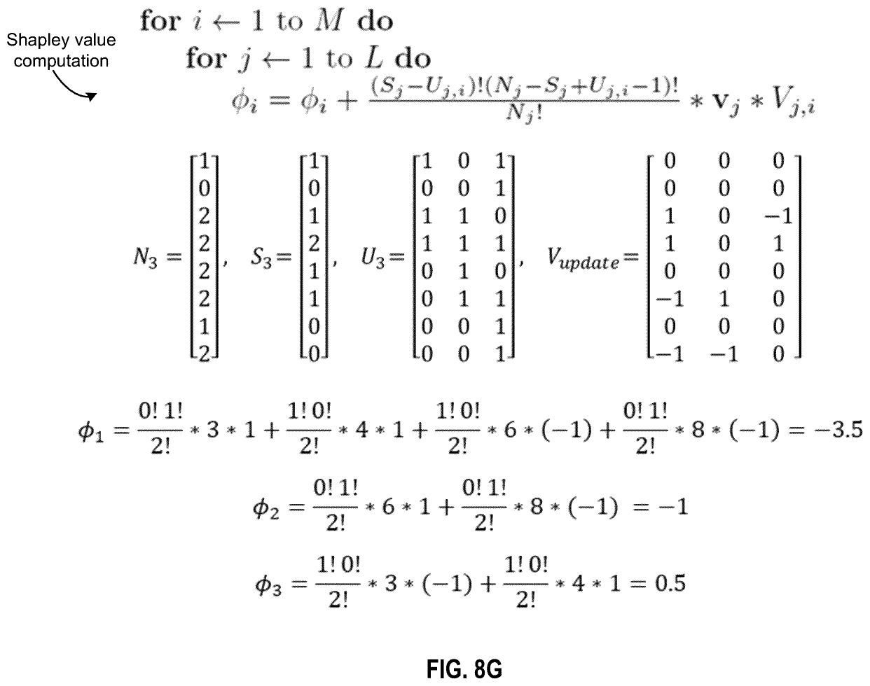

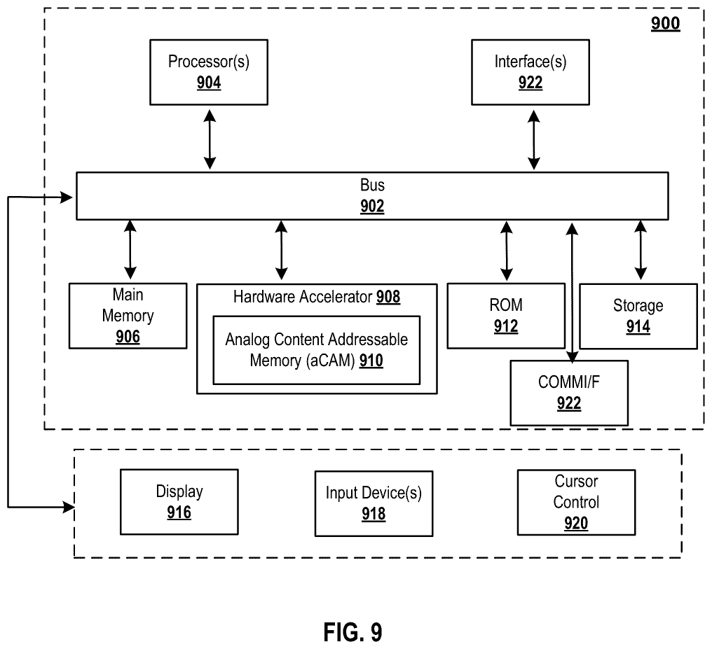

Examples of the present technology will be described in greater detail in conjunction with the following FIGS. Namely, FIGS. 1-6 describe general background that may be helpful for appreciating the advantages provided by treeSHAP-aCAMs when computing Shapley values over conventional hardware accelerators. FIGS. 7 and 8A-8G illustrate the new analog value/expression-oriented Shapley value computation methodology that examples of the presently disclosed technology leverage to implement Shapley problems in aCAMs. FIG. 9 depicts a block diagram of an example computer system in which various of the examples described herein may be implemented.

Referring now to FIG. 1, FIG. 1 depicts an example conventional aCAM cell 100. aCAM cell 100 may be an example of a 6 transistor-2 memristor (6T2M) aCAM cell.

aCAM cell 100 is electrically connected to a match line (i.e., ML 102) that may be pre-charged to a high voltage. aCAM cell 100 may “return a match” when the voltage across ML 102 remains high, and “return a mismatch” when the voltage across ML 102 is discharged. As described above, aCAM cell 100 may be an aCAM cell in a row of an aCAM. In certain examples, the match/mismatch result for the entire row (of which aCAM cell 100 is a part) may be output to another circuit (e.g., a resistive random access memory array (reRAM)) for further processing/classification.

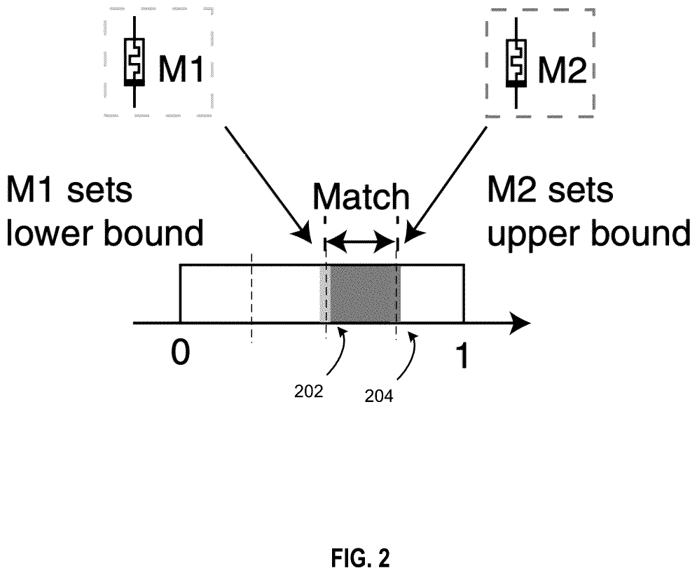

aCAM cell 100 also includes two data lines: DL1 106 and DL2 108 (running vertically in the example of FIG. 1) that are both electrically connected to an input data line: DL 104. aCAM cell 100 may receive an analog input voltage signal V(x) along DL 104 (here, analog input voltage signal V(x) may be an analog voltage signal that was converted from a digital input signal x). As depicted, DL1 106 and DL2 108 are both electrically connected to DL 104, and are electrically connected in parallel with respect to each other. Accordingly, analog input voltage signal V(x) may be applied along DL1 106 and DL2 108 respectively. As alluded to above, analog input voltage signal V(x) will eventually discharge ML 102 if analog input voltage signal V(x) is outside of the analog voltage range programmed in aCAM cell 100. Here, the analog voltage range stored by aCAM cell 100 is set/defined by programmed conductances of memristors M1 and M2. The programmed conductance of memristor M1 sets/defines the lower bound of the stored analog voltage range and the programmed conductance of memristor M2 sets/defines the upper bound of the stored analog voltage range (see e.g., FIG. 2).

As depicted, aCAM cell 100 includes a “lower bound side” 110 and an “upper bound side” 120, so-called because memristors M1 and M2 are programmed to set the lower bound and the upper bound of the analog voltage range stored by aCAM cell 100, respectively.

Lower bound side 110 includes a transistor T1 and memristor M1 electrically connected to each other in series. Memristor M1, in conjunction with transistor T1, define a voltage divider sub-circuit 112. As depicted, voltage divider sub-circuit 112 generates a gate voltage G1 across pull-down transistor T2. When the gate voltage G1 across pull-down transistor T2 exceeds a threshold value, pull-down transistor T2 will turn on/activate and “pull-down” (i.e., discharge) the voltage across ML 102, returning a mismatch. As described above, the voltage across pull-down transistor T2 can be influenced by: (1) the programmed conductance of memristor M1; and (2) analog input voltage signal V(x). In particular, when analog input voltage signal V(x) is greater than or equal to a threshold voltage (e.g., TL), transistor T1 will become more conductive (the programmed conductance of memristor M1 will remain the same during the search operation) and thus the voltage between SL_hi and SL_lo (typically at ground (GND)) will drop across memristor M1, resulting in a small gate voltage G1 that does not turn on/activate pull-down transistor T2, yielding a match result for lower bound side 110. Here, the value of T_{L} (i.e., the threshold voltage that will cause transistor T1 to become more conductive relative to memristor M1) can be programmed by programming the conductance of memristor M1. In this way, the programmed conductance of memristor M1 can be used to set the lower bound of the voltage range stored by aCAM cell 100.

Similar to lower bound side 110, upper bound side 120 includes a transistor T3 and memristor M2 electrically connected to each other in series. Memristor M2, in conjunction with transistor T3, define a voltage divider sub-circuit 122. Upper bound side 120 differs slightly from lower bound side 110 because voltage divider sub-circuit 122 is electrically connected to an input of an inverter 124 (here the series combination of transistors T4 and T5 operate in conjunction to comprise inverter 124). Inverter 124 operates to invert the voltage output by voltage divider sub-circuit 122. Because pull-down transistor T6 is electrically connected to the output of inverter 124, the inverted voltage output by inverter 124 controls the gate voltage G2 across pull-down transistor T6. Similar to above, when the gate voltage G2 across pull-down transistor T6 exceeds a threshold value, pull-down transistor T6 will turn on/activate and “pull-down” (i.e., discharge) the voltage across ML 102, returning a mismatch. As described above, the voltage across pull-down transistor T6 can be influenced by: (1) the programmed conductance of memristor M2; and (2) analog input voltage signal V(x). In particular, when analog input voltage signal V(x) is less than or equal to a threshold voltage (e.g., T_{H}), transistor T3 will not be highly conductive (e.g., have a conductance on the order of 10 nS as compared to a higher conductance state of e.g., 10 mS) and thus the voltage between SL_hi and SL_lo (typically at GND) will remain high across transistor T3, resulting in a high voltage output for voltage divider sub-circuit 122. However, when this high voltage is inverted by inverter 124, the inverted (now low) voltage causes a low gate voltage G2 that does not turn on/activate pull-down transistor T6, thus yielding a match result for upper bound side 120. Here, the value of T_{H} (i.e., the threshold voltage that will cause transistor T3 to not be highly conductive relative to memristor M2) can be programmed by programming the conductance of memristor M2. In this way, the programmed the conductance of memristor M2 can be used to set the upper bound of the voltage range stored by aCAM cell 100.

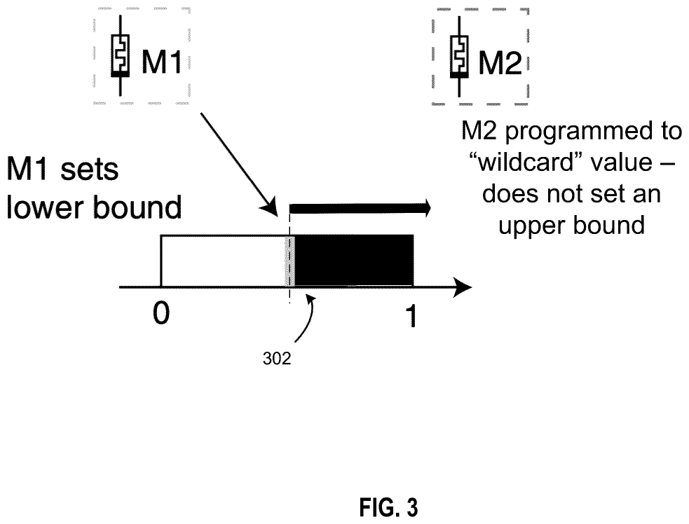

As alluded to above (and as will be described in greater detail in conjunction with FIG. 3), either or both of M1 and M2 may be programmed to wildcard values. If both M1 and M2 are programmed to wildcard values, aCAM cell 100 will practically always return a match. If only M1 is programmed to a wildcard value, aCAM cell 100 will essentially/practically only store an upper boundary voltage threshold. Conversely, if only M2 is programmed to a wildcard value, aCAM cell 100 will essentially/practically only store a lower boundary voltage threshold.

It should be understood that aCAM cell 100 is merely one example of an aCAM cell that can be used in conjunction with the presently disclosed technology. For example, certain implementations may utilize an aCAM cell that utilizes “pull-up” logic instead of the “pull-down” logic described in conjunction with FIG. 1.

FIG. 2 depicts an example diagram that illustrates how memristors M1 and M2 from aCAM cell 100 can be used to set a lower boundary voltage 202 and an upper boundary voltage 204 of a stored voltage range for aCAM cell 100. As depicted, aCAM cell 100 will return a match for an analog input voltage signal V(x) when analog input voltage signal V(x) is within the voltage range defined by lower boundary voltage 202 and upper boundary voltage 204. When analog input voltage signal V(x) is outside the voltage range defined by lower boundary voltage 202 and upper boundary voltage 204, aCAM cell 100 will return a mismatch. As described above, the conductance of memristors M1 and M2 respectively can be programmed to set/define lower boundary voltage 202 and upper boundary voltage 204.

FIG. 3 depicts an example diagram that illustrates how memristors M1 and M2 from aCAM cell 100 can be programmed to store an open-ended voltage range for aCAM cell 100 (i.e., a stored voltage range that is practically un-bounded on at least one end). As depicted, aCAM cell 100 will return a match for an analog input voltage signal V (x) whenever analog input voltage signal V(x) is greater than or equal to a lower boundary voltage 302 set by memristor M1. In other words, aCAM cell 100 will only return a mismatch when analog input voltage signal V(x) is less than lower boundary voltage 302. As described above, the conductance of memristor M1 can be programmed to set lower boundary voltage 302.

Here, FIG. 3 differs from FIG. 2 because the conductance of memristor M2 has been programmed to a “wildcard” value (sometimes referred to as a “don't care” value) that practically always returns a match for the upper boundary side 120 of aCAM cell 100 (i.e., returns a match for the upper boundary side 120 of aCAM cell 100 for any value of analog input voltage signal V(x) that would be received by aCAM cell 100 in practice). In general, deep conductance states of memristors can be used as wildcard values that practically set open-ended lower and upper boundaries for an aCAM cell. These deep conductance states (e.g., a deep low conductance state (DLCS) for a lower boundary wildcard value and a deep high conductance state (DHCS) for an upper boundary wildcard value) will be far outside the reliably programmable conductance ranges of the memristors. For example, if the memristors of aCAM cell 100 are programmed in the range [1 uS, 100 uS], deep conductance states of e.g., 0.01 uS and 1000 uS can be used for wildcard values that practically set open-ended lower and upper boundaries for aCAM cell 100 respectively. These deep conductance states are typically difficult to program in a reliable way, and are thus reserved for wildcard values where an error of e.g., 10% in programming can be acceptable. By programming memristors of aCAM cell 100 to wildcard values/deep conductance states, examples can set deep state lower and upper voltage boundaries that are practically open-ended. In other words, because in practice input/search voltage values received by an aCAM cell/sub-circuit will generally always be within the deep state lower and upper voltage boundaries set by programming memristors of an aCAM cell/sub-circuit to wildcard values, it can be generally stated that programmed wildcard values will always return a match.

Thus, in FIG. 3, memristor M2 practically sets an open-ended “upper boundary” for the analog voltage range stored by aCAM cell 100. It should be understood that in other examples, the conductance of memristor M2 may be programmed to set a “true” upper boundary voltage (i.e., an upper boundary voltage that that practically defines a “less than or equal to” condition at the upper boundary), and the conductance of memristor M1 may be programmed to a “wildcard” value that practically always returns a match for the lower boundary side 110 of aCAM cell 100 (i.e., such programming may practically store an open-ended voltage range that is only practically bounded at the upper end). Similarly, in certain examples the conductances of both memristors M1 and M2 may be programmed to “wildcard” values such that aCAM cell 100 practically always returns a match (i.e., returns a match for any value of analog input voltage signal V(x) that aCAM cell 100 would receive in practice).

As alluded to above, aCAM cells can be programmed to wildcard values to represent features not being evaluated in a root-to-leaf path.

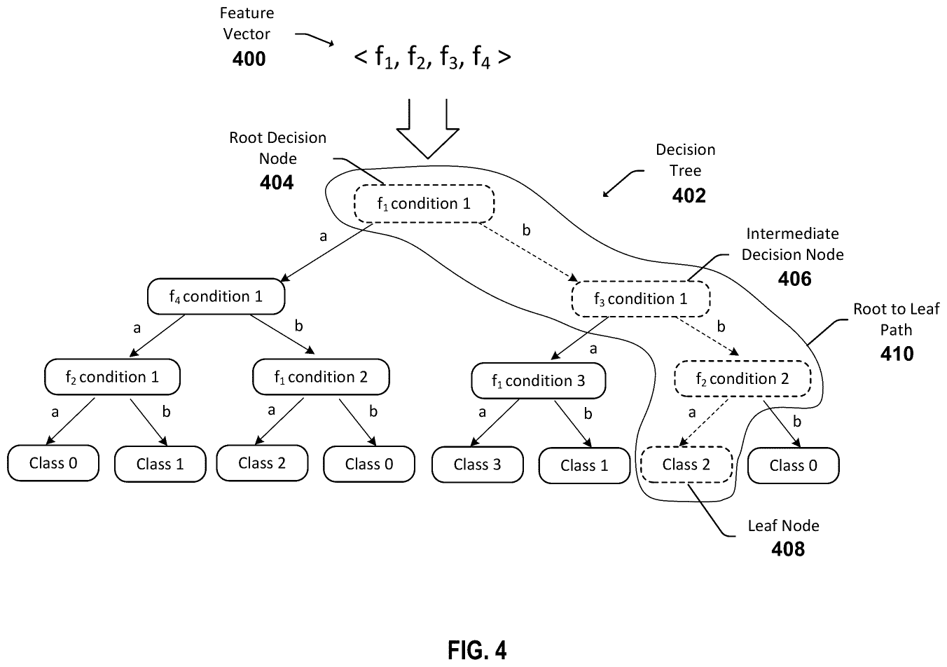

FIGS. 4-6 illustrate how an example decision tree 402 can be represented in an aCAM.

As depicted in FIG. 4, decision tree 402 may include a set of decision nodes including root decision node 404, various intermediate decision nodes (e.g., intermediate decision node 406), and various leaf nodes (e.g., leaf node 408) that represent terminus points of decision tree 402. It should be appreciated that decision tree 402 is merely an illustrative implementation of a decision tree.

Decision tree 402 may include multiple root-to-leaf paths. Each root-to-leaf path represents a traversal of a series of decision nodes. For example, a root-to-leaf path may begin at root decision node 404, traverse one or more intermediate decision nodes, and end at a leaf node. Each decision node traversed in the root-to-leaf path may represent an evaluable condition against which a feature of feature vector 400 may be evaluated. As such, the root-to-leaf path represents a series of evaluable conditions representative of a logical rule against which feature vector 400 can be evaluated.

In example root-to-leaf path 410 shown in FIG. 4, the series of evaluable conditions may begin with the condition evaluated at root decision node 404, which is illustratively depicted as involving feature f₁ of feature vector 400. In example decision tree 402, evaluating the condition represented by any given decision node may result in one of two possible outcomes, labeled as outcome “a” and outcome “b.” In some examples, outcome “b” represents the condition not being satisfied when evaluated and outcome “a” represents the condition being satisfied when evaluated. For instance, if the evaluable condition at root node 404 is whether f₁ is less than a value x₁, outcome “b” may represent a negative determination (i.e., f₁≥x₁) and outcome “a” may represent a positive determination (i.e., f₁<x₁). It should be appreciated that in other implementations more than two outcomes may be possible for an evaluable condition associated with a decision node.

In example root-to-leaf path 410, the outcome of the determination at the root decision node 404 is illustratively depicted as outcome “b,” which indicates that the condition evaluated at root decision node 404 involving feature f₁ is not satisfied. Based on this outcome, root-to-leaf path 410 transitions from root decision node 404 to intermediate decision node 406. Transitions from a first decision node to a second decision node within a given root-to-leaf path are represented as a combination of the condition evaluated at the first decision node and the outcome of that evaluation. For instance, the transition from root decision node 404 to intermediate decision node 406 in the example root-to-leaf path 410 is represented as f₁ condition 1b. Using this convention, the example root-to-leaf path 410 can be represented by the following decision node transitions: f₁ condition 1b to f₃ condition 1b to f₂ condition 2a to Class 2. Each other root-to-leaf path in decision tree 402 may be similarly represented as a series of decision node transitions indicative of the condition evaluated at each decision node in combination with the outcome of that evaluation.

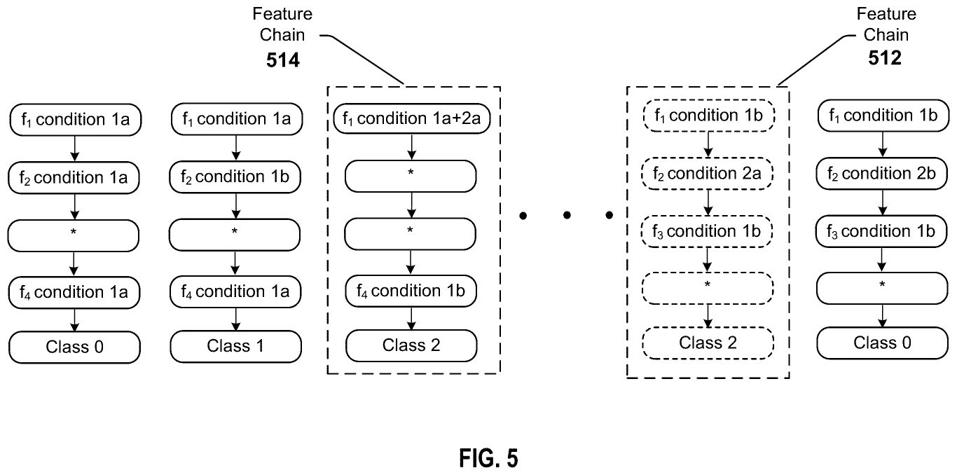

In various examples, the information contained in decision tree 402 may be converted to an alternate representation such as a tabular representation. In particular, each root-to-leaf path in decision tree 402 may be represented as a corresponding column in the tabular representation, referred to herein as a “feature chain” and illustrated in FIG. 5. For example, a decision tree can be reformulated for an aCAM implementation by: reformulating the decision tree to represent each root-to-leaf path as a feature chain with a series of feature chain nodes; combining multiple evaluable conditions of a root-to-leaf path involving an individual feature into one feature chain node; adding “wildcard” feature chain nodes to account for features not evaluated in a root-to-leaf path; and rotating (i.e., matrix transforming) the representation and mapping each feature chain to each row in the aCAM such that the columns of the aCAM correspond with feature vectors.

For instance, example root-to-leaf path 410 illustrated in FIG. 4 may be converted to feature chain 512. Feature chain nodes in feature chain 512 may correspond to one or more decision node transitions in the corresponding root-to-leaf path 410. More specifically, each feature chain node in feature chain 512 corresponds to a respective feature in feature vector 400. Because feature vector 400 is illustratively depicted as including four features (f₁, f₂, f₃, f₄), each feature chain associated with decision tree 402 may include four feature chain nodes corresponding to the four features, as well as a leaf node representing the leaf node of the corresponding root-to-leaf path. It should be appreciated that feature vector 400 may contain any number of features, in which case, corresponding feature chains may include a corresponding number of feature chain nodes along with a leaf node. In some examples, the leaf nodes may also correspond to a feature (e.g., an optimized parameter) that forms part of feature vector 400.

As alluded to above, certain root-to-leaf paths may not include evaluable conditions for one or more features. For instance, root-to-leaf path 410 does not include an evaluable condition for feature f₄. Accordingly, “wildcard” feature chain nodes (i.e., feature chain nodes comprising wildcard values) may be included to account for features that are not involved in any evaluable condition of a given root-to-leaf path. Feature chain 512 includes such a wildcard feature chain node for feature f₄ as root-to-leaf path 410 (corresponding with feature chain 512) does not include an evaluable condition involving feature f₄. This means that any value specified for feature f₄ in a search query would result in a match with respect to feature f₄ when evaluated against feature chain 512 after it has been encoded in an aCAM.

In connection with converting the representation of the set of domain logic rules from decision tree 402 to the tabular representation of FIG. 5, decision nodes within a given root-to-leaf path may be consolidated and/or reordered when determining the sequence of corresponding feature chain nodes in the feature chain that represents the root-to-leaf path. For instance, an evaluable condition involving feature f₃ occurs before an evaluable condition involving feature f₂ in the sequence of decision nodes traversed as part of root-to-leaf path 410. However, prior to encoding feature chain 512 in an aCAM, the sequence of evaluable conditions represented by root-to-leaf path 410 may be reordered to ensure that the sequence of the evaluable conditions in the corresponding feature chain 512 matches the sequence of features in feature vector 400. This reordering may occur, as needed, for each root-to-leaf path in decision tree 402 as part of converting the root-to-leaf path to a corresponding feature chain in the tabular representation.

For example, each feature chain in the tabular representation (e.g., each column in a table) may begin with a feature chain node representing an evaluable condition involving feature f₁ in the corresponding root-to-leaf path, followed by an evaluable condition involving feature f₂, and so on until the penultimate feature chain node in the feature chain is an evaluable condition involving the last feature fₙ of a feature vector (e.g., feature f₄ in feature vector 400), with the final node of the feature chain comprising an appropriate leaf node (alternatively each leaf node may correspond to a last feature fₙ in the feature vector).

In some examples, converting a root-to-leaf path to a corresponding feature chain may include consolidating two or more decision node transitions in the root-to-leaf path into a single feature chain node in a feature chain. For example, consider the root-to-leaf path in decision tree 402 that includes the following decision node transitions: f₁ condition 1a to f₄ condition 1b to f₁ condition 2a to Class 2. Two decision node transitions in this example path occur as a result of evaluating conditions involving feature f₁. As such, these two decision node transitions may be consolidated into the single feature chain node associated with feature f₁ in the corresponding feature chain 514 (represented as f₁ condition 1a+2a). For example, if f₁ condition 1a represents f₁>x₁ and if f₁ condition 2a represents f₁<x₂, the consolidated result (i.e., x₁<f₁<x₂) may be represented in the first feature chain node of feature chain 514 (i.e., the feature chain node associated with the feature f₁). Consolidating multiple decision node transitions involving a particular feature variable into a single consolidated feature chain node for that feature variable may increase the memory density and reduce the amount of area needed when encoding the set of logical rules represented by decision tree 402 into an aCAM.

The set of all root-to-leaf paths represented in decision tree 402 may be converted to a corresponding set of feature chains according to the methodology described above.

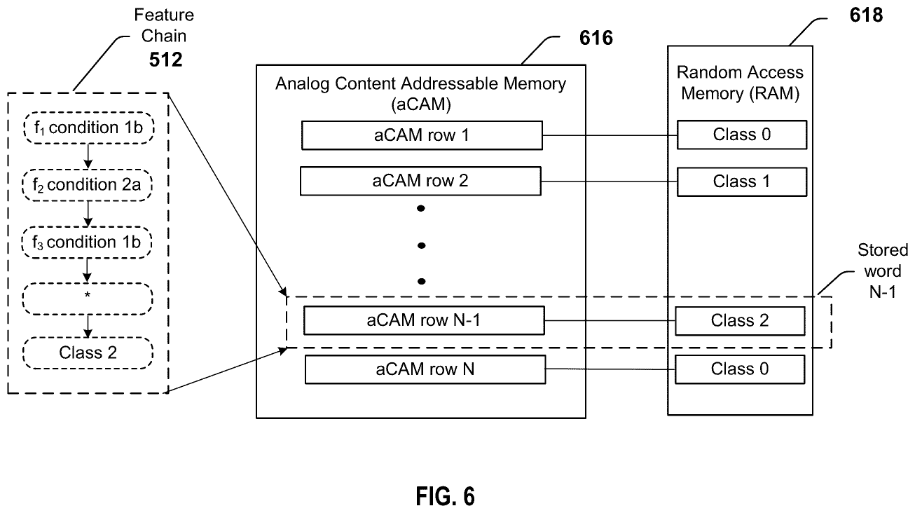

Once the conversion process is complete and the tabular representation of the domain logic rules is generated, each feature chain in the tabular representation may be rotated and mapped to a respective row of aCAM 616 in FIG. 6. In some examples, the sequence of feature chains in the tabular representation may be dictated by a convention that defines an order in which decision tree 402 is traversed to cover all root-to-leaf paths represented in decision tree 402. Further, in some examples, the sequence of feature chains in the tabular representation may be mapped and encoded to rows of aCAM 616 in the same sequence. In other examples, the sequencing of the feature chains may not be relevant as long as each root-to-leaf node in decision tree 402 is converted to a respective corresponding feature chain, and each feature chain is mapped to and encoded in a respective row of aCAM 616.

As shown in FIG. 6, feature chain 512 may be mapped to and encoded in a particular row of aCAM 616 (e.g., aCAM row N-1). More specifically, each value represented in each feature chain node of feature chain 512 may be stored using a respective corresponding one or more aCAM cells in row N-1. Each other feature chain such as, for example, feature chain 514 may be similarly mapped to and encoded in a respective row of aCAM 616 (not illustrated).

In some examples, the value represented in a feature chain node of feature chain 512 may in fact be a range of values. As previously noted, aCAM 616 provides the capability to store and encode such ranges of values. The number of aCAM cells required to encode the values/ranges of values corresponding to a particular feature (e.g., feature f₁) across all feature chains (i.e., the number of aCAM cell columns corresponding to feature f₁) may depend on the level of precision required to encode such values/ranges of values. For a feature in feature vector 400 that is a categorical variable that can take on only a limited number of discrete values (e.g., the set of all origin or destination airports), a single column of aCAM cells may be sufficient to represent all stored values for that feature across the set of domain logic rules. On the other hand, for a feature that corresponds to a numeric variable capable of taking on a large number of possible values (e.g., a continuous range of values), multiple columns of aCAM cells may be required to provide the bit precision needed to store such values.

In some examples, an output parameter of each feature chain (domain logic rule) encoded in aCAM 616 may in fact be stored in a memory array separate from aCAM 616. For instance, as illustratively shown in FIG. 4, each of the leaf nodes of decision tree 402 represent classification outputs that may be stored in a random access memory (RAM) 618 separate from aCAM 616 (in some examples RAM 618 may comprise a resistive random access memory (ReRAM)). This may then allow for multiple matches to be returned for a search query. In some examples, a search query may conform to the format of feature vector 400 and may specify a discrete value, a range of values, or a “wildcard” value for each search variable (i.e., each feature in feature vector 400). The search query may then be searched, in parallel, against each row in aCAM 616 to determine if the search query matches the stored values in any such row. Each row of aCAM 616 may represent a stored word that corresponds to a particular feature chain, and thus, a particular root-to-leaf path in decision tree 402. In some examples, a stored word may include only those values stored in a particular row of aCAM 616. In other examples, a stored word may include the values of a particular aCAM row as well as a corresponding value of the output parameter (e.g., the classification output value) stored in RAM 618.

In some examples, the output parameter (e.g., the classification outputs represented by the leaf nodes of decision tree 402) may be a parameter that a user seeks to optimize. For example, a search query may specify a maximum or minimum allowable value for the optimized parameter, in which case, any row in aCAM 616 that matches each of the constrained and/or flexible parameter values specified in the search query and that satisfies the value specified for the optimized parameter may be returned as a match result. More specifically, the address of any such matching row in aCAM 616 may be returned as a search result. Optionally, the corresponding value for the optimized parameter stored in RAM 618 (or the memory address in RAM 618 for the corresponding value) may also be returned.

In other examples, rather than searching for stored rows in aCAM 616 that correspond to output parameter values that are below or above a specified value as part of an optimization process, a search query may instead specify a value for the output parameter that requires an exact match among the values for the output parameter stored in RAM 618. For instance, in such examples, a search query may result in a match only if: (1) all other search parameter values specified in the search query match corresponding stored values in a given row of aCAM 616; and (2) the output parameter value specified in the search query exactly matches a value stored in RAM 618 that corresponds to that row in aCAM 616. Thus, in such examples, a search query that includes search variable values that satisfy the first four feature chain nodes of feature chain 512, but that specifies “Class 3” for the output parameter value would not produce a match at stored word N-1.

In still other examples, a search query may specify an exclusionary value for the output parameter. For instance, the search query may specify “Class 2” as an exclusionary value for the output parameter in FIG. 4. Such an example search query would then produce a matching result for any row in aCAM 616, and thus, any feature chain in the tabular representation and corresponding root-to-leaf path in decision tree 402, that matches each of the other constrained parameters in the search query and that corresponds to a stored output parameter value other than “Class 2.” This may represent a mechanism for optimizing the output parameter by specifying values to be excluded from matching rather than through iterative adjustment of the optimized parameter.

FIG. 7 illustrates an example process 700 for computing Shapley values using an aCAM, in accordance with various examples of the presently disclosed technology. Process 700 may be performed by a treeSHAP-aCAM of the presently disclosed technology.

Before describing process 700 in more detail, it may be useful to provide some background on Shapley value computation/Shapley values.

As alluded to above, a Shapley value is a solution concept in cooperative game theory where a coalition of “players” cooperates and achieves an overall gain from the cooperation. In this context, a Shapley value (e.g., a multi-valued vector) measures the contribution that individual players in a coalition game make to an overall gain achieved through coalitional cooperation. In other words, the Shapley value assigns a unique distribution—among individual players in the coalition game—of a total surplus/gain generated by coalitional cooperation. Eq. 2 below illustrates an example computation for a Shapley value (i.e., φᵢ(ν)).

$${φ}_{i} ( v ) = {\sum }_{S ⊆ N \backslash \{ i \}} \begin{matrix}\frac{\vert S \vert ! ( \vert N \vert - \vert S \vert - 1 ) !}{\vert N \vert !} \\ Coalition probability \\ weight ( W )\end{matrix} \begin{matrix}( v ( S ⋃ \{ i \} ) - v ( S ) ) \\ Marginal \\ contribution ( Δ v )\end{matrix} \qquad Eq . 2$$

As depicted, the term

$$\frac{\vert S \vert ! ( \vert N \vert - \vert S \vert - 1 ) !}{\vert N \vert !}$$

represents a coalition occurrence probability weight while the term [symbol] (S ∪{i})− [symbol] (S) represents a marginal contribution from all coalitions. N (e.g., a matrix) may comprise all possible player coalitions (i.e., subsets of players). Thus, N\{i} may comprise all the possible player coalitions that exclude an i-th player. S is one coalition/subset of N, and |S| represents the size of coalition S. [symbol] is a characteristic function that maps coalitions of players to real numbers. Accordingly, [symbol] (S)—sometimes called the worth of coalition S—describes a total expected sum of payoffs the members of coalition S can obtain through cooperation.

Related to above, a Shapley value for an i-th feature of a decision tree model prediction f for a foreground sample x^{f} can be computed as illustrated in Eqs. 3 below:

$${φ}_{i} ( f , {x}^{f} ) = \frac{1}{\vert B \vert} {\sum }_{{x}^{b} ∈ B} {φ}_{i} ( f , {x}^{f} , {x}^{b} ) = \frac{1}{\vert B \vert} {\sum }_{{x}^{b} ∈ B} {\sum }_{S ⊆ N \backslash \{ i \}} \frac{\vert S \vert ! ( \vert N \vert - \vert S \vert - 1 ) !}{\vert N \vert !} ( f ( {h}^{S ⋃ \{ i \}} ) - f ( {h}^{S} ) ) \qquad Eqs . 3$$

$$( S ) = f ( {h}^{S} ) , where {h}_{i}^{S} = {x}_{i}^{f} if i ∈ S , {x}_{i}^{b} otherwise$$

Here, x^{b} represents a background sample, which is used for representing missing features. In contrast to conventional binary representations of features in the above-described coalition game, the values of a foreground sample in a decision tree model can be analog values. Unlike with binary values (e.g., zero or one), there is no single counterpart for analog values. Thus, examples of the presently disclosed technology can leverage a background sample (i.e., x^{b})—comprised of analog values—that corresponds to the absence of feature(s). Accordingly, presence of feature(s) can correspond with the foreground sample while absence of feature(s) corresponds with the background sample.

h is a function mapping coalition S to a real number vector. B is a number of background samples in the problem.

As alluded to above, while Shapley values can provide useful/insightful human-interpretable explanations for machine-learning applications, a historical barrier to real-time (or close to real-time) machine-learning model interpretability has been the large complexity, long processing times, and large amount of hardware overhead required to compute Shapley values via conventional methods. Real-time (or close to real-time) human-interpretability can be extremely advantageous in time-sensitive applications (e.g., guided surgical interventions) where a human needs to make a quick decision based on a machine-learning model output. Accordingly, there is a serious opportunity for a hardware accelerator that can compute Shapley values with improved speed/efficiency.

Against this backdrop, examples of the presently disclosed technology provide hardware accelerators (referred to herein as treeSHAP-aCAMs) that compute Shapley values with improved speed/efficiency leveraging the unique parallel search and analog capabilities of aCAMs. For example, the parallel search capability of a treeSHAP-aCAM enables evaluation of all root-to-leaf paths of a decision tree (programmed into separate rows of the treeSHAP-aCAM) in a single clock cycle, greatly reducing time required to compute Shapley values. Relatedly, the treeSHAP-aCAM's ability to store/evaluate analog values (as opposed to merely binary values), can reduce footprint and hardware (e.g., reduce a number of CAM cells) required to perform Shapley value computations. Accordingly, treeSHAP-aCAMs can compute Shapley values more rapidly/efficiently than other types of hardware accelerators that e.g., implement algorithms that traverse root-to-leaf paths of decision trees node-to-node.

As alluded to above, implementing (i.e., programming and evaluating) a Shapley problem using an aCAM presents a technological/computational challenge because Shapley problems are traditionally formulated using binary values/expressions. By contrast, aCAMs are traditionally used to implement problems involving analog values/expressions. As alluded to above, this analog capability of aCAMs allows them to implement problems more efficiently (e.g., with less hardware) than binary/digital alternatives.

To address the technological/computational challenge described above, examples of the presently disclosed technology provide a new methodology which enables Shapley value computation using analog values/expressions that are compatible with, and leverage, the unique analog and parallel search capabilities of aCAMs. Thus, leveraging this new analog value/expression-oriented Shapley value computation methodology, treeSHAP-aCAMs can utilize aCAMs to compute Shapley values more rapidly/efficiently than other types of hardware accelerators.

Process 700 of FIG. 7 illustrates such an analog value/expression-oriented Shapley value computation methodology. Again, process 700 may be performed by a treeSHAP-aCAM of the presently disclosed technology. The treeSHAP-aCAM may comprise an aCAM (e.g., aCAM 616 of FIG. 6), a combination of logic circuits that (among other things) iteratively compute Shapley value computation parameters based on match line outputs from the aCAM, and one or more hardware processors that (among other things) compute Shapley values based on final iterations of the Shapley value computation parameters.

As depicted, the treeSHAP-aCAM can begin process 700 by programming rows of the aCAM to store root-to-leaf paths of a decision tree. For example, if the decision tree comprises a number (L) root-to-leaf paths, the treeSHAP-aCAM can program the (L) root-to-leaf paths into (L) rows of the aCAM. In various implementations, such programming may be implemented by the one or more hardware processors of the treeSHAP-aCAM and/or logic circuits of the treeSHAP-aCAM.

The decision tree may comprise evaluable conditions involving (M) features. As described in conjunction with FIGS. 4-6, programming rows of the aCAM to store root-to-leaf paths of the decision tree may involve converting the root-to-leaf paths to feature chain representations. The feature chain representations for each root-to-leaf path may comprise (M) feature chain nodes corresponding with the (M) features of the decision tree. These feature chain representations may then be programmed to respective rows of the aCAM. As described above, leaves of the root-to-leaf paths may be programmed into rows of a ReRAM (e.g., RAM 618) that is electrically connected to match lines of the aCAM rows. As alluded to above, programming the feature chain representations to the rows of the aCAM may involve programming constituent aCAM cells to store evaluable conditions involving individual features. This can be achieved by programming lower boundary voltage thresholds (represented as TI in FIG. 7) and/or upper boundary voltage thresholds (represented as Th in FIG. 7) into the individual aCAM cells. As described above, this may involve programming conductances of memristors of the constituent aCAM cells.

As depicted in line 13 of process 700, once the root-to-leaf paths of the decision tree have been programmed to separate rows of the aCAM, the treeSHAP-aCAM can apply an i-th foreground input vector (e.g., x_{fi}) to the aCAM. The i-th foreground input vector x_{fi} may comprise (M) individual values. As alluded to above, these (M) values may correspond with analog voltage signals that are applied to columns of the aCAM. One of the (M) values of the i-th foreground input vector x_{fi} may represent an i-th feature of a foreground sample x_{f} to be evaluated against the decision tree. The foreground sample x_{f} may also comprise (M) features—which can be evaluated against the evaluable conditions of the decision tree that involve a corresponding number of (M) features.

The remaining (M−1) values of the i-th foreground input vector x_{fi} may comprise/represent wildcard values that always return a match. Accordingly, application of the i-th foreground input vector x_{fi} to the aCAM can evaluate, in an isolated manner, the i-th feature of the foreground sample x_{f} against evaluable conditions involving the i-th feature of the decision tree. As alluded to above, due to the unique parallel search capability of the aCAM, such an evaluation can be made for all root-to-leaf paths of the decision tree (programmed to separate rows of the aCAM) in a single clock cycle.

As depicted, match line outputs (e.g., voltage signals) returned from the aCAM responsive to application of the i-th foreground input vector x_{fi} may be represented by an i-th foreground match line output vector y_{fi}.

After applying the i-th foreground input vector x_{fi} to the aCAM, the treeSHAP-aCAM can apply an i-th background input vector x_{bi} to the aCAM (see e.g., line 14 of process 700). The i-th background input vector x_{bi} may also comprise (M) individual values (as alluded to above, these (M) values may correspond with analog voltage signals that are applied to columns of the aCAM). One of the (M) values of the i-th background input vector x_{bi} may represent an i-th feature of a background sample x_{b} to be evaluated against the decision tree. The background sample x_{b} may also comprise (M) features—which can be evaluated against the evaluable conditions of the decision tree that involve a corresponding number of (M) features.

The remaining (M−1) values of the i-th background input vector x_{bi} may comprise/represent wildcard values that always return a match. Accordingly, application of the i-th background input vector x_{bi} to the aCAM can evaluate, in an isolated manner, the i-th feature of the background sample x_{b} against evaluable conditions involving the i-th feature of the decision tree. As alluded to above, due to the unique parallel search capability of the aCAM, such an evaluation can be made for all root-to-leaf paths of the decision tree (programmed to separate rows of the aCAM) in a single clock cycle.

Match line outputs (e.g., voltage signals) returned from the aCAM responsive to application of the i-th background input vector x_{bi} may be represented by an i-th background match line output vector y_{bi}.

In accordance with lines 15-19 of process 700, the treeSHAP-aCAM can compute an i-th iteration of Shapley value computation parameters (i.e., parameters used by the treeSHAP-aCAM to compute a Shapley value for the foreground sample).

For example, line 15 of process 700 involves computing an i-th iteration of a vector N representing, for each root-to-leaf path of the decision tree, a total number of unique features in the root-to-leaf path. As alluded to above, the vector N may have a dimension corresponding to the number of root-to-leaf paths of the decision tree (L). This dimension may also correspond with the number of programmed rows of the aCAM (also (L)).

Line 16 of process 700 involves computing an i-th iteration of a vector S representing, for each root-to-leaf path of the decision tree, a total number of features of the root-to-leaf path that match the foreground sample. Again, the vector S may have a dimension corresponding to the number of root-to-leaf paths of the decision tree/the number of programmed rows of the aCAM (L).

Line 17 of process 700 involves computing an i-th iteration of a matrix U representing, for each root-to-leaf path of the decision tree, offsets to the vector S applied when computing the Shapley value for the foreground sample. The matrix U may include a number of rows corresponding to the number of root-to-leaf paths of the decision tree (L). The matrix U may include a number of columns corresponding to the number of features of the foreground and background samples (M).

Line 18 of process 700 involves computing an i-th iteration of a matrix V representing, for each root-to-leaf path of the decision tree, contribution types (e.g., positive (+1), negative (−1), or null (0)) for the root-to-leaf path. Again, the matrix V may include a number of rows corresponding to the number of root-to-leaf paths of the decision tree (L). The matrix V may include a number of columns corresponding to the number of features of the foreground and background samples (M).

Line 19 of process 700 involves computing an i-th iteration of a vector P representing, for each root-to-leaf path of the decision tree, path validity of the root-to-leaf path (e.g., 0 for an invalid path and 1 for a valid path). Again, the vector P may have a dimension corresponding to the number of root-to-leaf paths of the decision tree/the number of programmed rows of the aCAM (L).

As alluded to above, the treeSHAP-aCAM can iterate the operations of lines 13-19 a total of (M) times in order to: (1) evaluate each of the (M) features of the foreground and background samples (x_{f} and x_{b} respectively) against the root-to-leaf paths of the decision tree; and (2) compute final iterations of the Shapley value computation parameters. Accordingly, the treeSHAP-aCAM can complete the iterative operations of lines 13-19 (see e.g., line 20 of process 700) upon applying all the requisite foreground and background input vectors to the aCAM and computing the final iterations of the Shapley value computation parameters.

As depicted at line 21 of process 700, the treeSHAP-aCAM can update the final iteration of the matrix V by performing a conjunction between the final iteration of the matrix V and the final iteration of the vector P. This operation may be performed to ensure that only valid root-to-leaf paths of the decision tree contribute to a computed Shapley value.

As depicted at line 22, the treeSHAP-aCAM can compute a Shapley value for the foreground sample based on the final iteration of the vector N, the final iteration of the vector S, the final iteration of the matrix U, the updated final iteration of the matrix V, and a vector v representing leaves of the decision tree (here, the vector v may also have a dimension corresponding to the number of root-to-leaf paths of the decision tree (L)). As alluded to above, the Shapley value may comprise a multi-valued vector that measures contributions from the individual features of the foreground sample to a decision tree-based model decision.

In various examples, the treeSHAP-aCAM can leverage the expression from Eq. 4 below to compute the Shapley value for the foreground sample based on these final iterations of the Shapley value computation parameters:

$$for i ← 1 to M do \qquad Eq . 4$$

$$for j ← 1 to L do$$

$${ϕ}_{i} = {ϕ}_{i} + \frac{( {S}_{j} - {U}_{j , i} ) ! ( {N}_{j} - {S}_{j} + {U}_{j , i} - 1 ) !}{{N}_{j} !} * {V}_{j} * {V}_{j , i}$$

Again, (L) may represent the number of root-to-leaf paths of the decision tree, and correspondingly, the number of programmed aCAM rows. j may comprise an index for (L). i may comprise an index for the number of features of the foreground and background samples (M).

FIGS. 8A-8E depict an example use case for utilizing process 700 to compute a Shapley value, in accordance with examples of the presently disclosed technology. Namely. FIGS. 8A-8E illustrate how a Shapley value can be computed for a foreground sample x_{f} that is evaluated against a decision tree 800.

As depicted in FIG. 8A, decision tree 800 includes eight unique root-to-leaf paths (terminating at each one of B leaves 1-8 respectively). Decision tree 800 also includes evaluable conditions involving three features: f1; f2; and f3. The root-to-leaf paths of decision tree 800 may be programmed to rows of an aCAM (e.g., aCAM 616) in the manner described above. Here, eight rows of the aCAM may be programmed to store the eight unique root-to-leaf paths of decision tree 800. For example, a first/top row of the aCAM may be programmed to store a first root-to-leaf path, a second/second-from-top row of the aCAM may be programmed to store a second root-to-leaf path, a third/third-from-top row of the aCAM may be programmed to store a third root-to-leaf path, etc. Relatedly, aCAM cells of a first/leftmost column of the aCAM may store evaluable conditions involving feature f1; aCAM cells of a second/middle column of the aCAM may store evaluable conditions involving feature f2; and aCAM cells of a third/rightmost column of the aCAM may store evaluable conditions involving feature f3. A ReRAM (e.g., RAM 618) may store the leaves of decision tree 800.

As depicted in the specific example of FIGS. 8A-8G, foreground sample x_{f} comprises three features: f1=0.2; f2=0.5; and f3=0.9. Relatedly, background sample x_{b} also comprises three features: f1=0.6; f2=1.0; and f3=0.3. As alluded to above, the features of the foreground and background samples may be evaluated against the evaluable conditions of decision tree 800 by applying input vectors (e.g., voltage signals representing features of the foreground and background samples) to the aCAM programmed to store the root-to-leaf paths of decision tree 800. Namely, values of features corresponding with feature f1 may be applied down the first/leftmost column of the aCAM, values of features corresponding with feature f2 may be applied down the second/middle column of the aCAM, and values of features corresponding with feature f3 may be applied down the third/rightmost column of the aCAM.

As depicted in FIG. 8A, a first foreground input vector x_{f1} may comprise three values: 0.2, which represents the first feature (i.e., f1=0.2) of the foreground sample x_{f}; and two wildcard values corresponding with the second and third features of the foreground sample x_{f} which are not being evaluated in the first iteration of process 700. Similarly, a first background input vector x_{b1} may comprise three values: 0.6, which represents the first feature (i.e., f1=0.6) of the background sample x_{b}; and two wildcard values corresponding with the second and third features of the background sample x_{b} which are not being evaluated in the first iteration of process 700.

FIG. 8B illustrates an example representation for a first foreground match line output vector y_{f1}. As illustrated in FIG. 8B, when the first foreground input vector x_{f1} is applied to the aCAM, a match line of the first/top row of the aCAM returns a match (e.g., a voltage signal indicating a match). Thus, the value of the first foreground match line output vector y_{f1} corresponding with the first row of the aCAM is a one. Conversely, when the first foreground input vector x_{f1} is applied to the aCAM, a match line of the second/second-from-top row of the aCAM returns a mismatch (e.g., a voltage signal indicating a mismatch). Thus, the value of the first foreground match line output vector y_{f1} corresponding with the second row of the aCAM is a zero. As illustrated in FIG. 8B, the third and fourth rows of the aCAM also return a match when the first foreground input vector x_{f1} is applied to the aCAM—and thus their corresponding values in the first foreground match line output vector y_{f1} are also one. Conversely, the fifth-eighth rows of the aCAM return a mismatch when the first foreground input vector x_{f1} is applied to the aCAM—and thus their corresponding values in the first foreground match line output vector y_{f1} are zero. A first background match line output vector y_{b1} that represents match line outputs of the aCAM responsive to application of the first background input vector x_{b1}, and subsequent iterations of foreground/background match line output vectors may be generated in the same/similar manner.

FIG. 8C illustrates how first iterations of the Shapley value computation parameters can be computed based on the first foreground match line output vector y_{f1} and the first background match line output vector y_{b1}. As alluded to above, the first foreground match line output vector y_{f1} may represent match line outputs from the aCAM responsive to application of the first foreground input vector x_{f1}. Relatedly, the first background match line output vector y_{b1} may represent match line outputs from the aCAM responsive to application of the first background input vector x_{b1}.

As depicted, computing the first iteration of the vector N (i.e., N₁) may comprise adding, to an all-zero vector, an exclusive OR (XOR) between the first foreground match line output vector y_{f1} and the first background match line output vector y_{b1}.

Computing the first iteration of the vector S (i.e., S₁) may comprise adding, to an all-zero vector, a conjunction (i.e., a logical AND operation) between the first foreground match line output vector y_{f1} and a negation (i.e., a logical NOT operation) of the first background match line output vector y_{b1}.

Computing the first iteration of the matrix U (i.e., U₁) may comprise populating a first column of the matrix U with the conjunction between the first foreground match line output vector y_{f1} and the negation of the first background match line output vector y_{b1}.

Computing the first iteration of the matrix V (i.e., V₁) may comprise populating a first column of the matrix V with a subtraction, from the conjunction between the first foreground match line output vector y_{f1} and the negation of the first background match line output vector y_{b1}, of a conjunction between a negation of the first foreground match line output vector y_{f1} and the first background match line output vector y_{b1}.

Finally, computing the first iteration of the vector P (i.e., P₁) may comprise performing a conjunction between an all-one vector and a disjunction (i.e., a logical OR operation) between the first foreground match line output vector y_{f1} and the first background match line output vector y_{b1}.

FIG. 8D illustrates how second iterations of the Shapley value computation parameters can be computed based on a second foreground match line output vector y_{f2} and a second background match line output vector y_{b2}.

As alluded to above, the second foreground match line output vector y_{f2} may represent match line outputs from the aCAM responsive to application of a second foreground input vector x_{f2}. Here, the second foreground input vector x_{f2} may also comprise three values: a first wildcard value, corresponding with the first feature of the foreground sample which is not being evaluated in the second iteration of process 700; 0.5 representing the second feature of the foreground sample (i.e., f2=0.5); and a second wildcard value, corresponding with the third feature of the foreground sample which is not being evaluated in the second iteration of process 700.

Relatedly, the second background match line output vector y_{b2} may represent match line outputs from the aCAM responsive to application of a second background input vector x_{b2}. Here, the second background input vector x_{b2} may also comprise three values: a first wildcard value, corresponding with the first feature of the background sample which is not being evaluated in the second iteration of process 700; 1.0 representing the second feature of the background sample (i.e., f2=1.0); and a second wildcard value, corresponding with the third feature of the background sample which is not being evaluated in the second iteration of process 700.

As depicted, computing the second iteration of the vector N (i.e., N₂) may comprise adding, to the first iteration of the vector N (i.e., N₁), an exclusive OR (XOR) between the second foreground match line output vector y_{f2} and the second background match line output vector y_{b2}.

Computing the second iteration of the vector S (i.e., S₂) may comprise adding, to the first iteration of the vector S (i.e., S₁), a conjunction (i.e., a logical AND operation) between the second foreground match line output vector y_{f2} and a negation (i.e., a logical NOT operation) of the second background match line output vector y_{b2}.

Computing the second iteration of the matrix U (i.e., U₂) may comprise populating a second column of the matrix U with the conjunction between the second foreground match line output vector y_{f2} and the negation of the second background match line output vector y_{b2}.

Computing the second iteration of the matrix V (i.e., V₂) may comprise populating a second column of the matrix V with a subtraction, from the conjunction between the second foreground match line output vector y_{f2} and the negation of the second background match line output vector y_{b2}, of a conjunction between a negation of the second foreground match line output vector y_{f2} and the second background match line output vector y_{b2}.

Finally, computing the second iteration of the vector P (i.e., P₂) may comprise performing a conjunction between the first iteration of the vector P (i.e., P₁) and a disjunction (i.e., a logical OR operation) between the second foreground match line output vector y_{f2} and the second background match line output vector y_{b2}.

FIG. 8E illustrates how third iterations of the Shapley value computation parameters can be computed based on a third foreground match line output vector y_{f3} and a third background match line output vector y_{b3}. In the specific example of FIGS. 8A-8E, the third iterations of the Shapley value computation parameters are the final iterations of the Shapley value computation parameters.

As alluded to above, the third foreground match line output vector y_{f3} may represent match line outputs from the aCAM responsive to application of a third foreground input vector x_{f3}. Here, the third foreground input vector x_{f3} may also comprise three values: a first wildcard value, corresponding with the first feature of the foreground sample which is not being evaluated in the second iteration of process 700; a second wildcard value, corresponding with the second feature of the foreground sample which is not being evaluated in the second iteration of process 700; and 0.9 representing the third feature of the foreground sample (i.e., f3=0.9).

Relatedly, the third background match line output vector y_{b3} may represent match line outputs from the aCAM responsive to application of a third background input vector x_{b3}. Here, the third background input vector x_{b3} may also comprise three values: a first wildcard value, corresponding with the first feature of the background sample which is not being evaluated in the second iteration of process 700; a second wildcard value, corresponding with the second feature of the background sample which is not being evaluated in the second iteration of process 700; and 0.3 representing the third feature of the background sample (i.e., f3=0.3).

As depicted, computing the third iteration of the vector N (i.e., N₃) may comprise adding, to the second iteration of the vector N (i.e., N₂), an exclusive OR (XOR) between the third foreground match line output vector y_{f3} and the third background match line output vector y_{b3}.

Computing the third iteration of the vector S (i.e., S₃) may comprise adding, to the second iteration of the vector S (i.e., S₂), a conjunction (i.e., a logical AND operation) between the third foreground match line output vector y_{f3} and a negation (i.e., a logical NOT operation) of the third background match line output vector y_{b3}.

Computing the third iteration of the matrix U (i.e., U₃) may comprise populating a third column of the matrix U with the conjunction between the third foreground match line output vector y_{f3} and the negation of the third background match line output vector y_{b3}.

Computing the third iteration of the matrix V (i.e., V₃) may comprise populating a third column of the matrix V with a subtraction, from the conjunction between the third foreground match line output vector y_{f3} and the negation of the third background match line output vector y_{b3}, of a conjunction between a negation of the third foreground match line output vector y_{f3} and the third background match line output vector y_{b3}.

Finally, computing the third iteration of the vector P (i.e., P₃) may comprise performing a conjunction between the second iteration of the vector P (i.e., P₂) and a disjunction (i.e., a logical OR operation) between the third foreground match line output vector y_{f3} and the third background match line output vector y_{b3}.

FIG. 8F illustrates how the final iteration of the matrix V can be updated by performing a conjunction between the final iteration of the matrix V (i.e., V₃) and the final iteration of the vector P (i.e., P₃).

FIG. 8G illustrates how a Shapley value may be computed for the foreground sample x_{f} based on the final iteration of the vector N (i.e., N₃), the final iteration of the vector S (i.e., S₃), the final iteration of the matrix U (i.e., U₃), the updated final iteration of the matrix V (i.e., V_{update}), and a vector v representing leaves of the decision tree 800.

FIG. 9 depicts a block diagram of an example computer system 900 in which various of the examples described herein may be implemented.

The computer system 900 includes a bus 912 or other communication mechanism for communicating information, one or more hardware processors 904 coupled with bus 912 for processing information. Hardware processor(s) 904 may be, for example, one or more general purpose microprocessors.

The computer system 900 also includes a main memory 906, such as a random access memory (RAM), cache and/or other dynamic storage devices, coupled to bus 912 for storing information and instructions to be executed by processor 904. Main memory 906 also may be used for storing temporary variables or other intermediate information during execution of instructions to be executed by processor 904. Such instructions, when stored in storage media accessible to processor 904, render computer system 900 into a special-purpose machine that is customized to perform the operations specified in the instructions.

The computer system 900 further includes a read only memory (ROM) 912 or other static storage device coupled to bus 912 for storing static information and instructions for processor 904. A storage device 914, such as a magnetic disk, optical disk, or USB thumb drive (Flash drive), etc., is provided and coupled to bus 912 for storing information and instructions.

Computer system 900 additionally includes hardware accelerator 908. Hardware accelerator 908 may be configured to execute instructions (i.e. programming or software code) stored in the main memory 906, read-only memory (ROM) 912, and/or storage device 914 to encode a set of logical rules embodied in a data structure (e.g., a decision tree) into an aCAM 910. In an example implementation, the exemplary hardware accelerator 908 may include multiple integrated circuits, which in turn, can include Application-Specific Integrated Circuits (ASICs), Field Programmable Gate Arrays (FPGAs) or other Very Large Scale Integrated circuits (VLSIs). The integrated circuits of the exemplary hardware accelerator 908 may be specifically optimized to perform a discrete subset of computer processing operations, or execute a discrete subset of computer-executable instructions, in an accelerated manner. For example, hardware accelerator 908 may be configured or manufactured to implement a set of logical rules embodied in a data structure such as the decision tree on the aCAM 910.

The aCAM 910 may include a non-volatile memory built using technologies that include for instance, resistive switching memory (i.e. memristor), phase change memory, magneto-resistive memory, ferroelectric memory, some other resistive random access memory device (Re-RAM), or combinations of those technologies. More generally, the aCAM 910 may be implemented using technologies that permit the aCAM 910 to hold its contents even when power is lost or otherwise removed. Thus, data in the aCAM 910 “persists” and the aCAM 910 can act as what is known as a “non-volatile memory.”

The computer system 900 may be coupled via bus 912 to a display 916, such as a liquid crystal display (LCD) (or touch screen), for displaying information to a computer user. An input device 918, including alphanumeric and other keys, is coupled to bus 912 for communicating information and command selections to processor 904. Another type of user input device is cursor control 920, such as a mouse, a trackball, or cursor direction keys for communicating direction information and command selections to processor 904 and for controlling cursor movement on display 916. In some embodiments, the same direction information and command selections as cursor control may be implemented via receiving touches on a touch screen without a cursor.

The computing system 900 may include a user interface module to implement a GUI that may be stored in a mass storage device as executable software codes that are executed by the computing device(s). This and other modules may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables.

In general, the word “component,” “engine,” “system,” “database,” data store,” and the like, as used herein, can refer to logic embodied in hardware or firmware, or to a collection of software instructions, possibly having entry and exit points, written in a programming language, such as, for example, Java, C or C++. A software component may be compiled and linked into an executable program, installed in a dynamic link library, or may be written in an interpreted programming language such as, for example, BASIC, Perl, or Python. It will be appreciated that software components may be callable from other components or from themselves, and/or may be invoked in response to detected events or interrupts. Software components configured for execution on computing devices may be provided on a computer readable medium, such as a compact disc, digital video disc, flash drive, magnetic disc, or any other tangible medium, or as a digital download (and may be originally stored in a compressed or installable format that requires installation, decompression or decryption prior to execution). Such software code may be stored, partially or fully, on a memory device of the executing computing device, for execution by the computing device. Software instructions may be embedded in firmware, such as an EPROM. It will be further appreciated that hardware components may be comprised of connected logic units, such as gates and flip-flops, and/or may be comprised of programmable units, such as programmable gate arrays or processors.

The computer system 900 may implement the techniques described herein using customized hard-wired logic, one or more ASICs or FPGAs, firmware and/or program logic which in combination with the computer system causes or programs computer system 900 to be a special-purpose machine. According to one embodiment, the techniques herein are performed by computer system 900 in response to processor(s) 904 executing one or more sequences of one or more instructions contained in main memory 906. Such instructions may be read into main memory 906 from another storage medium, such as storage device 914. Execution of the sequences of instructions contained in main memory 906 causes processor(s) 904 to perform the process steps described herein. In alternative embodiments, hard-wired circuitry may be used in place of or in combination with software instructions.

The term “non-transitory media,” and similar terms, as used herein refers to any media that store data and/or instructions that cause a machine to operate in a specific fashion. Such non-transitory media may comprise non-volatile media and/or volatile media. Non-volatile media includes, for example, optical or magnetic disks, such as storage device 914. Volatile media includes dynamic memory, such as main memory 906. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, and networked versions of the same.

Non-transitory media is distinct from but may be used in conjunction with transmission media. Transmission media participates in transferring information between non-transitory media. For example, transmission media includes coaxial cables, copper wire and fiber optics, including the wires that comprise bus 912. Transmission media can also take the form of acoustic or light waves, such as those generated during radio-wave and infra-red data communications.

The computer system 900 also includes a communication/network interface 922 coupled to bus 912. Network interface 922 provides a two-way data communication coupling to one or more network links that are connected to one or more local networks. For example, communication interface 922 may be an integrated services digital network (ISDN) card, cable modem, satellite modem, or a modem to provide a data communication connection to a corresponding type of telephone line. As another example, network interface 922 may be a local area network (LAN) card to provide a data communication connection to a compatible LAN (or WAN component to communicated with a WAN). Wireless links may also be implemented. In any such implementation, network interface 918 sends and receives electrical, electromagnetic or optical indicators that carry digital data streams representing various types of information.

A network link typically provides data communication through one or more networks to other data devices. For example, a network link may provide a connection through local network to a host computer or to data equipment operated by an Internet Service Provider (ISP). The ISP in turn provides data communication services through the world wide packet data communication network now commonly referred to as the “Internet.” Local network and Internet both use electrical, electromagnetic or optical indicators that carry digital data streams. The indicators through the various networks and the indicators on network link and through communication interface 922, which carry the digital data to and from computer system 900, are example forms of transmission media.

The computer system 900 can send messages and receive data, including program code, through the network(s), network link and communication interface 918. In the Internet example, a server might transmit a requested code for an application program through the Internet, the ISP, the local network and the communication interface 922.

The received code may be executed by processor 904 as it is received, and/or stored in storage device 914, or other non-volatile storage for later execution.

Each of the processes, methods, and algorithms described in the preceding sections may be embodied in, and fully or partially automated by, code components executed by one or more computer systems or computer processors comprising computer hardware. The one or more computer systems or computer processors may also operate to support performance of the relevant operations in a “cloud computing” environment or as a “software as a service” (SaaS). The processes and algorithms may be implemented partially or wholly in application-specific circuitry. The various features and processes described above may be used independently of one another, or may be combined in various ways. Different combinations and sub-combinations are intended to fall within the scope of this disclosure, and certain method or process blocks may be omitted in some implementations. The methods and processes described herein are also not limited to any particular sequence, and the blocks or states relating thereto can be performed in other sequences that are appropriate, or may be performed in parallel, or in some other manner. Blocks or states may be added to or removed from the disclosed example embodiments. The performance of certain of the operations or processes may be distributed among computer systems or computers processors, not only residing within a single machine, but deployed across a number of machines.

As used herein, a circuit might be implemented utilizing any form of hardware, software, or a combination thereof. For example, one or more processors, controllers, ASICs, PLAS, PALs, CPLDs, FPGAs, logical components, software routines or other mechanisms might be implemented to make up a circuit. In implementation, the various circuits described herein might be implemented as discrete circuits or the functions and features described can be shared in part or in total among one or more circuits. Even though various features or elements of functionality may be individually described or claimed as separate circuits, these features and functionality can be shared among one or more common circuits, and such description shall not require or imply that separate circuits are required to implement such features or functionality. Where a circuit is implemented in whole or in part using software, such software can be implemented to operate with a computing or processing system capable of carrying out the functionality described with respect thereto, such as computer system 900.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps.

Terms and phrases used in this document, and variations thereof, unless otherwise expressly stated, should be construed as open ended as opposed to limiting. Adjectives such as “conventional,” “traditional,” “normal,” “standard,” “known,” and terms of similar meaning should not be construed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

What is claimed is:

1. A system comprising:
an analog content addressable memory (aCAM), wherein each row of the aCAM is programmed to represent a separate root-to-leaf path of a decision tree comprising evaluable conditions involving (M) features; and
one or more processing resources operative to:
(a) apply a first foreground input vector to the aCAM, wherein:
a first value of (M) total values of the first foreground input vector represents a first feature of (M) features from a foreground sample, and
remaining (M−1) values of the (M) total values of the first foreground input vector comprise wildcard values;
(b) apply a first background input vector to the aCAM, wherein:
a first value of (M) total values of the first background input vector represents a first feature of (M) features from a background sample, and
remaining (M−1) values of the (M) total values of the first background input vector represent wildcard values;
(c) based on match line outputs from the aCAM responsive to application of the first and foreground and background input vectors, compute a first iteration of Shapley value computation parameters;
(d) iterate steps (a)-(c) for each of the (M) features of the foreground and background samples to generate subsequent iterations of the Shapley value computation parameters; and
(e) based on final iterations of the Shapley value computation parameters, compute a Shapley value for the foreground sample.

2. The system of claim 1, wherein iterating the steps (a)-(c) for a second feature of the (M) features of the foreground and background samples comprises:
(a) applying a second foreground input vector to the aCAM, wherein:
a second value of (M) total values of the second foreground input vector represents a second feature of the (M) features from the foreground sample, and
remaining (M−1) values of the (M) total values of the second foreground input vector represent wildcard values;
(b) applying a second background input vector to the aCAM, wherein:
a second value of (M) total values of the second background input vector represents a second feature of the (M) features from the background sample, and
remaining (M−1) values of the (M) total values of the second background input vector represent wildcard values; and
(c) based on match line outputs from the aCAM responsive to application of the second foreground and background input vectors, computing a second iteration of the Shapley value computation parameters.

3. The system of claim 2, wherein the Shapley value computation parameters comprise:
a vector N representing, for each root-to-leaf path of the decision tree, a total number of unique features in the root-to-leaf path;
a vector S representing, for each root-to-leaf path of the decision tree, a total number of features of the root-to-leaf path that match the foreground sample;
a matrix U representing, for each root-to-leaf path of the decision tree, offsets to the vector S applied when computing the Shapley value for the foreground sample;
a matrix V representing, for each root-to-leaf path of the decision tree, contribution types for the root-to-leaf path; and
a vector P representing, for each root-to-leaf path of the decision tree, path validity of the root-to-leaf path.

4. The system of claim 3, wherein:
computing the first iteration of the vector N comprises adding, to an all-zero vector, an exclusive OR (XOR) between a first foreground match line output vector y_{f1} representing match line outputs responsive to application of the first foreground input vector to the aCAM and a first background match line output vector y_{b1} representing match line outputs responsive to application of the first background input vector to the aCAM;
computing the first iteration of the vector S comprises adding, to an all-zero vector, a conjunction between the first foreground match line output vector y_{f1} and a negation of the first background match line output vector y_{b1};
computing the first iteration of the matrix U comprises populating a first column of the matrix U with the conjunction between the first foreground match line output vector y_{f1} and the negation of the first background match line output vector y_{b1};
computing the first iteration of the matrix V comprises populating a first column of the matrix V with a subtraction, from the conjunction between the first foreground match line output vector y_{f1} and the negation of the first background match line output vector y_{b1}, of a conjunction between a negation of the first foreground match line output vector y_{f1} and the first background match line output vector y_{b1}; and
computing the first iteration of the vector P comprises performing a conjunction between an all-one vector and a disjunction between the first foreground match line output vector y_{f1} and the first background match line output vector y_{b1}.

5. The system of claim 4, wherein:
computing the second iteration of the vector N comprises adding, to the first iteration of the vector N, an XOR between a second foreground match line output vector y_{f2} representing match line outputs responsive to application of the second foreground input vector to the aCAM and a second background match line output vector y_{b2} representing match line outputs responsive to application of the second background input vector to the aCAM;
computing the second iteration of the vector S comprises adding, to the first iteration of the vector S, a conjunction between the second foreground match line output vector y_{f2} and a negation of the second background match line output vector y_{b2};
computing the second iteration of the matrix U comprises populating a second column of the matrix U with the conjunction between the second foreground match line output vector y_{f2} and the negation of the second background match line output vector y_{b2};
computing the second iteration of the matrix V comprises populating a second column of the matrix V with a subtraction, from the conjunction between the second foreground match line output vector y_{f2} and the negation of the second background match line output vector y_{b2}, of a conjunction between a negation of the second foreground match line output vector y_{f2} and the second background match line output vector y_{b2}; and
computing the second iteration of the vector P comprises performing a conjunction between the first iteration of the vector P and a disjunction between the second foreground match line output vector y_{f2} and the second background match line output vector y_{b2}.

6. The system of claim 5, wherein the one or more processing resources are further operative to:
responsive to final iteration of steps (a)-(c), update the final iteration of the matrix V by performing a conjunction between the final iteration of the matrix V and the final iteration of the vector P; and
wherein computing the Shapley value for the foreground sample based on the final iterations of the Shapley value computation parameters comprises computing the Shapley value for the foreground sample based on the final iteration of the vector N, the final iteration of the vector S, the final iteration of the matrix U, the updated final iteration of the matrix V, and a vector v representing leaf values of the decision tree.

7. The system of claim 1, further comprising a resistive random-access memory (ReRAM) that stores leaf values of the decision tree.

8. The system of claim 7, wherein:
a first row of the aCAM is programmed to store a first root-to-leaf path of the decision tree;
a first row of the ReRAM is programmed to store a leaf of the first root-to-leaf path and is electrically connected to a match line of the first row of the aCAM;
a second row of the aCAM is programmed to store a second root-to-leaf path of the decision tree; and
a second row of the ReRAM is programmed to store a leaf of the second root-to-leaf path and is electrically connected to a match line of the second row of the aCAM.

9. The system of claim 7, wherein:
a first column of the aCAM stores evaluable conditions of the decision tree corresponding with the first features of the foreground and background samples;
a second column of the aCAM stores evaluable conditions of the decision tree corresponding with the second features of the foreground and background samples;
the first value of the (M) total values of the first foreground input vector is applied to the first column of the aCAM;
the first value of the (M) total values of the first background input vector is applied to the first column of the aCAM;
the second value of the (M) total values of the second foreground input vector is applied to the second column of the aCAM; and
the second value of the (M) total values of the second background input vector is applied to the second column of the aCAM.

10. The system of claim 8, wherein:
a first aCAM cell of the first row of the aCAM is programmed to store one or more evaluable conditions of the first root-to-leaf path corresponding with the first features of the foreground and background samples;
the first aCAM cell comprises two memristors; and
programming the first aCAM cell to store the one or more evaluable conditions of the first root-to-leaf path corresponding with the first features of the foreground and background samples comprises programming conductances of the two memristors.

11. The system of claim 10, wherein programming the conductances of the two memristors causes the first aCAM cell to store a lower boundary threshold voltage and an upper boundary threshold voltage.

12. A method comprising:
(a) applying a first foreground input vector to an analog content addressable memory (aCAM), wherein:
each row of the aCAM is programmed to represent a separate root-to-leaf path of a decision tree comprising evaluable conditions involving (M) features,
a first value of (M) total values of the first foreground input vector represents a first feature of (M) features from a foreground sample, and
remaining (M−1) values of the (M) total values of the first foreground input vector comprise wildcard values;
(b) apply a first background input vector to the aCAM, wherein:
a first value of (M) total values of the first background input vector represents a first feature of (M) features from a background sample, and
remaining (M−1) values of the (M) total values of the first background input vector represent wildcard values;
(c) based on match line outputs from the aCAM responsive to application of the first and foreground and background input vectors, computing a first iteration of Shapley value computation parameters;
(d) iterating steps (a)-(c) for each of the (M) features of the foreground and background samples to generate subsequent iterations of the Shapley value computation parameters; and
(e) based on final iterations of the Shapley value computation parameters, computing a Shapley value for the foreground sample.

13. The method of claim 12, wherein iterating the steps (a)-(c) for a second feature of the (M) features of the foreground and background samples comprises:
(a) applying a second foreground input vector to the aCAM, wherein:
a second value of (M) total values of the second foreground input vector represents a second feature of the (M) features from the foreground sample, and
remaining (M−1) values of the (M) total values of the second foreground input vector represent wildcard values;
(b) applying a second background input vector to the aCAM, wherein:
a second value of (M) total values of the second background input vector represents a second feature of the (M) features from the background sample, and
remaining (M−1) values of the (M) total values of the second background input vector represent wildcard values; and
(c) based on match line outputs from the aCAM responsive to application of the second foreground and background input vectors, computing a second iteration of the Shapley value computation parameters.

14. The method of claim 13, the Shapley value computation parameters comprise:
a vector N representing, for each root-to-leaf path of the decision tree, a total number of unique features in the root-to-leaf path;
a vector S representing, for each root-to-leaf path of the decision tree, a total number of features of the root-to-leaf path that match the foreground sample;
a matrix U representing, for each root-to-leaf path of the decision tree, offsets to the vector S applied when computing the Shapley value for the foreground sample;
a matrix V representing, for each root-to-leaf path of the decision tree, contribution types for the root-to-leaf path; and
a vector P representing, for each root-to-leaf path of the decision tree, path validity of the root-to-leaf path.

15. The method of claim 14, wherein:
computing the first iteration of the vector N comprises adding, to an all-zero vector, an exclusive OR (XOR) between a first foreground match line output vector y_{f1} representing match line outputs responsive to application of the first foreground input vector to the aCAM and a first background match line output vector y_{b1} representing match line outputs responsive to application of the first background input vector to the aCAM;
computing the first iteration of the vector S comprises adding, to an all-zero vector, a conjunction between the first foreground match line output vector y_{f1} and a negation of the first background match line output vector y_{b1};
computing the first iteration of the matrix U comprises populating a first column of the matrix U with the conjunction between the first foreground match line output vector y_{f1} and the negation of the first background match line output vector y_{b1};
computing the first iteration of the matrix V comprises populating a first column of the matrix V with a subtraction, from the conjunction between the first foreground match line output vector y_{f1} and the negation of the first background match line output vector y_{b1}, of a conjunction between a negation of the first foreground match line output vector y_{f1} and the first background match line output vector y_{b1}; and
computing the first iteration of the vector P comprises performing a conjunction between an all-one vector and a disjunction between the first foreground match line output vector y_{f1} and the first background match line output vector y_{b1}.

16. The method of claim 15, wherein:
computing the second iteration of the vector N comprises adding, to the first iteration of the vector N, an XOR between a second foreground match line output vector y_{f2} representing match line outputs responsive to application of the second foreground input vector to the aCAM and a second background match line output vector y_{b2} representing match line outputs responsive to application of the second background input vector to the aCAM;
computing the second iteration of the vector S comprises adding, to the first iteration of the vector S, a conjunction between the second foreground match line output vector y_{f2} and a negation of the second background match line output vector y_{b2};
computing the second iteration of the matrix U comprises populating a second column of the matrix U with the conjunction between the second foreground match line output vector y_{f2} and the negation of the second background match line output vector y_{b2};
computing the second iteration of the matrix V comprises populating a second column of the matrix V with a subtraction, from the conjunction between the second foreground match line output vector y_{f2} and the negation of the second background match line output vector y_{b2}, of a conjunction between a negation of the second foreground match line output vector y_{f2} and the second background match line output vector y_{b2}; and
computing the second iteration of the vector P comprises performing a conjunction between the first iteration of the vector P and a disjunction between the second foreground match line output vector y_{f2} and the second background match line output vector y_{b2}.

17. The method of claim 16, further comprising:
responsive to final iteration of steps (a)-(c), updating the final iteration of the matrix V by performing a conjunction between the final iteration of the matrix V and the final iteration of the vector P; and
wherein computing the Shapley value for the foreground sample based on the final iterations of the Shapley value computation parameters comprises computing the Shapley value for the foreground sample based on the final iteration of the vector N, the final iteration of the vector S, the final iteration of the matrix U, the updated final iteration of the matrix V, and a vector v representing leaf values of the decision tree.

18. A system comprising:
an analog content addressable memory (aCAM), wherein each row of the aCAM is programmed to represent a separate root-to-leaf path of a decision tree comprising evaluable conditions involving (M) features;
logic circuits electrically connected to match lines of the aCAM, the logic circuits operative to:
(a) apply a first foreground input vector to the aCAM, wherein:
a first value of (M) total values of the first foreground input vector represents a first feature of (M) features from a foreground sample, and
remaining (M−1) values of the (M) total values of the first foreground input vector comprise wildcard values;
(b) apply a first background input vector to the aCAM, wherein:
a first value of (M) total values of the first background input vector represents a first feature of (M) features from a background sample, and
remaining (M−1) values of the (M) total values of the first background input vector represent wildcard values;
(c) based on match line outputs from the aCAM responsive to application of the first and foreground and background input vectors, compute a first iteration of Shapley value computation parameters; and
(d) iterate steps (a)-(c) for each of the (M) features of the foreground and background samples to generate subsequent iterations of the Shapley value computation parameters; and
a processor operative to compute a Shapley value based on final iterations of the Shapley value computation parameters.

19. The system of claim 18, wherein iterating the steps (a)-(c) for a second feature of the (M) features of the foreground and background samples comprises:
(a) applying a second foreground input vector to the aCAM, wherein:
a second value of (M) total values of the second foreground input vector represents a second feature of the (M) features from the foreground sample, and
remaining (M−1) values of the (M) total values of the second foreground input vector represent wildcard values;
(b) applying a second background input vector to the aCAM, wherein:
a second value of (M) total values of the second background input vector represents a second feature of the (M) features from the background sample, and
remaining (M−1) values of the (M) total values of the second background input vector represent wildcard values; and
(c) based on match line outputs from the aCAM responsive to application of the second foreground and background input vectors, computing a second iteration of the Shapley value computation parameters.

20. The system of claim 19, wherein the Shapley value computation parameters comprise:
a vector N representing, for each root-to-leaf path of the decision tree, a total number of unique features in the root-to-leaf path;
a vector S representing, for each root-to-leaf path of the decision tree, a total number of features of the root-to-leaf path that match the foreground sample;
a matrix U representing, for each root-to-leaf path of the decision tree, offsets to the vector S applied when computing the Shapley value for the foreground sample;
a matrix V representing, for each root-to-leaf path of the decision tree, contribution types for the root-to-leaf path; and
a vector P representing, for each root-to-leaf path of the decision tree, path validity of the root-to-leaf path.
